(19) United States
(12) Patent Application Publication
(10) Pub. No.: US 2026/0181853 A1
(43) Pub. Date: Jun. 25, 2026

(54) SEMICONDUCTOR DEVICES INCLUDING BIT LINES

(71) Applicant: Samsung Electronics Co., Ltd., Suwon-si (KR)

(72) Inventors: Juho Lee, Suwon-si (KR); Sungjin Kim, Suwon-si (KR); Yongkwan Kim, Suwon-si (KR); Kilho Lee, Suwon-si (KR); Daewon Ha, Suwon-si (KR); Sungduk Hong, Suwon-si (KR)

(21) Appl. No.: 19/263,653

(22) Filed: Jul. 9, 2025

(30) Foreign Application Priority Data
Dec. 20, 2024 (KR) 10-2024-0192879

(51) Int. Cl. H10B 12/00; G11C 5/06; H10B 41/10; H10B 41/30; H10D 62/80

(52) U.S. Cl. CPC H10B 12/00; G11C 5/063; H10B 41/10; H10B 41/30; H10D 62/875; H10B 12/01

(57) ABSTRACT

A semiconductor device includes: semiconductor material layers including first channel regions and charge storage regions and extending in a first horizontal direction; first word lines vertically overlapping the first channel regions and extending in a second horizontal direction; first bit lines being first ends of the semiconductor material layers in the first horizontal direction, and extending in the vertical direction proximate the first ends; second channel regions vertically overlapping the charge storage regions; and second bit lines being second ends of the semiconductor material layers in the first horizontal direction, and extending in the vertical direction proximate the second ends. Each of the first bit lines includes a first conductive layer and a first liner layer surrounding a side surface of the first conductive layer. The first liner layers of the first bit lines contact the first channel regions, extend in the vertical direction, and include an oxide semiconductor material.

### CROSS-REFERENCE TO RELATED APPLICATION(S)

This application claims benefit of priority under 35 U.S.C. § 119 to Korean Patent Application No. 10-2024-0192879 filed on Dec. 20, 2024 in the Korean Intellectual Property Office, the disclosure of which is incorporated herein by reference in its entirety.

### BACKGROUND

The present inventive concept relates generally to a semiconductor device including a bit line.

As demand for high performance, high speed, and/or multifunctionality of semiconductor devices increases, a degree of integration of semiconductor devices is increasing. In manufacturing a semiconductor device with a fine pattern corresponding to the trend for a high degree of integration of semiconductor devices, it is required to implement patterns having a fine width or a fine separation distance.

### SUMMARY

An aspect of the present inventive concept is to provide a semiconductor device including bit lines shared by adjacent memory cells.

According to an aspect of the present inventive concept, a semiconductor device includes: semiconductor material layers extending in a first horizontal direction and spaced apart from each other in the first horizontal direction, each of the semiconductor material layers including a first channel region and a charge storage region; first word lines overlapping respective first channel regions of the semiconductor material layers in a vertical direction, and extending in a second horizontal direction, intersecting the first horizontal direction; first bit lines being first ends of the semiconductor material layers in the first horizontal direction, and extending in the vertical direction next to the first end adjacent to the first channel region; second channel regions overlapping respective charge storage regions of the semiconductor material layers in the vertical direction; and second bit lines being second ends of the semiconductor material layers in the first horizontal direction, and extending in the vertical direction next to the second end adjacent to the charge storage region. Each of the first bit lines includes a first conductive layer and a first liner layer extending around a side surface of the first conductive layer. The first liner layer of each of the first bit lines is in contact with a corresponding one of the first channel regions, extends in the vertical direction, and includes an oxide semiconductor material.

According to an aspect of the present inventive concept, a semiconductor device includes: memory cells, each of the memory cells including a first transistor including a first channel region, a second transistor including a second channel region, and a charge storage region on the same level as the first channel region, overlapping the second channel region in a vertical direction, and disposed in a first horizontal direction; a first bit line extending in the vertical direction between the memory cells and electrically connected to the first transistors; and a second bit line extending in the vertical direction between the memory cells and electrically connected to the second transistors. The memory cells include a first memory cell and a second memory cell, adjacent in the first horizontal direction. The first memory cell and the second memory cell share the first bit line. The first bit line includes a first conductive layer and a first liner layer extending around a side surface of the first conductive layer. The first liner layer extends in the vertical direction and is in contact with the first channel regions.

According to an aspect of the present inventive concept, a semiconductor device includes: a semiconductor material layer extending in a first horizontal direction and including a first channel region and a charge storage region; a first word line overlapping the first channel region of the semiconductor material layer in a vertical direction and extending in a second horizontal direction, intersecting the first horizontal direction; a second channel region overlapping the charge storage region of the semiconductor material layer in the vertical direction; a second word line contacting the second channel region and extending in the second horizontal direction between the second channel region and the first word line; a first bit line extending in the vertical direction from one side of the first channel region of the semiconductor material layer; and a second bit line extending in the vertical direction from one side of the second channel region.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a circuit diagram of a memory cell of a semiconductor device according to an example embodiment;

FIG. 2 is a conceptual perspective view of a semiconductor device according to an example embodiment;

FIG. 3 is a plan view of a semiconductor device according to an example embodiment;

FIG. 4 is a vertical cross-sectional view along lines I-I′ and II-II′ of the semiconductor device illustrated in FIG. 3;

FIG. 5 is an enlarged view of a portion of the semiconductor device illustrated in FIG. 4;

FIG. 6 is a vertical cross-sectional view along line III-III′ of the semiconductor device illustrated in FIG. 3;

FIG. 7 is a vertical cross-sectional view along lines IV-IV′ and V-V′ of the semiconductor device illustrated in FIG. 3;

FIGS. 8 and 9 are vertical cross-sectional views of semiconductor devices according to example embodiments;

FIGS. 10 and 11 are vertical cross-sectional views of semiconductor devices according to example embodiments;

FIGS. 12 to 14 are vertical cross-sectional views of semiconductor devices according to example embodiments;

FIG. 15 is a conceptual perspective view of a semiconductor device according to an example embodiment; and

FIGS. 16A to 30C are plan views and vertical cross-sectional views illustrating intermediate processes in a method of manufacturing a semiconductor device according to an example embodiment.

### DETAILED DESCRIPTION

Hereinafter, preferred embodiments will be described with reference to the attached drawings.

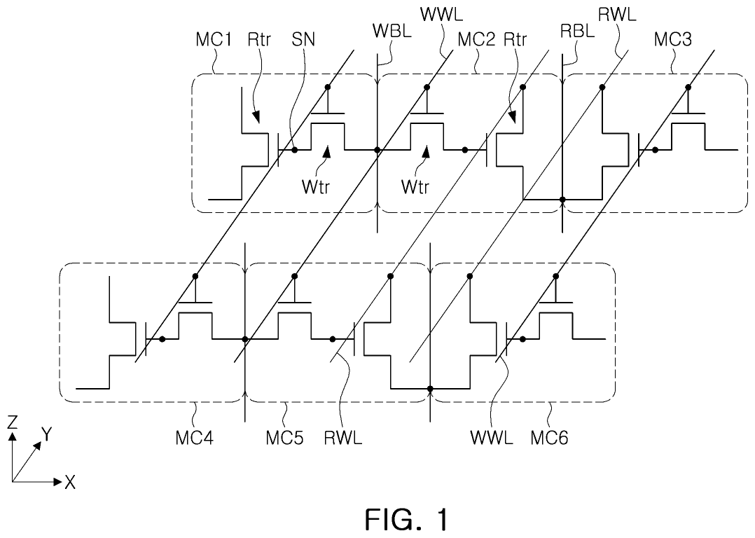

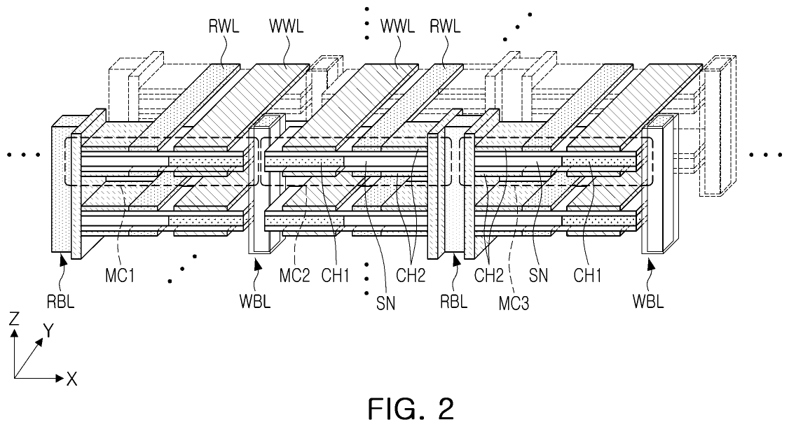

FIG. 1 is a circuit diagram of a memory cell of a semiconductor device according to an example embodiment. FIG. 2 is a conceptual perspective view of a semiconductor device according to an example embodiment.

Referring to FIGS. 1 and 2, memory cells MC1, MC2, MC3, MC4, MC5, and MC6 may be disposed in a horizontal direction. For example, a first memory cell MC1, a second memory cell MC2, and a third memory cell MC3 may be sequentially disposed in an X-direction, and a fourth memory cell MC4, a fifth memory cell MC5, and a sixth memory cell MC6 may be sequentially disposed in the X-direction. The fourth memory cell MC4, the fifth memory cell MC5, and the sixth memory cell MC6 may be spaced apart from the first memory cell MC1, the second memory cell MC2, and the third memory cell MC3 in a Y-direction, respectively. FIG. 1 illustrates memory cells MC1, MC2, MC3, MC4, MC5, and MC6 disposed on the same vertical level, and the memory cells may be disposed in multiple layers in a vertical direction (Z-direction). The X-direction and Y-direction may be horizontal directions that intersect one another, and the Z-direction may be a vertical direction perpendicular to the X-direction and Y-direction.

Each memory cell MC1, MC2, MC3, MC4, MC5, and MC6 may include a write transistor Wtr, a read transistor Rtr, and a storage node SN. The storage node SN may function as a gate (e.g., a floating gate) of the read transistor Rtr, and may be electrically connected to the write transistor Wtr. For example, the storage node SN may be electrically connected to a channel CH1 of the write transistor Wtr.

Each of the memory cells MC1, MC2, MC3, MC4, MC5, and MC6 may operate as a DRAM memory cell in which a write operation for storing data and a read operation for reading data are performed, and may not include a capacitor. For example, each of the memory cells MC1, MC2, MC3, MC4, MC5, and MC6 may store data in the storage node SN instead of in a capacitor. Each of the memory cells MC1, MC2, MC3, MC4, MC5, and MC6 may be referred to as a 2T (two-transistor) memory cell.

A gate of the write transistor Wtr may be electrically connected to a write word line WWL extending in the Y-direction. For example, gates of write transistors Wtr of the second memory cell MC2 and the fifth memory cell MC5 may be electrically connected to the same write word line WWL. A channel CH2 of the read transistor Rtr may be electrically connected to a read word line RWL extending in the Y-direction. For example, channels CH2 of the read transistors Rtr of the second memory cell MC2 and the fifth memory cell MC5 may be electrically connected to the same read word line RWL.

A write bit line WBL and a read bit line RBL may extend in the vertical direction between the memory cells MC1, MC2, MC3, MC4, MC5, and MC6. The write bit lines WBL and the read bit lines RBL may be alternately disposed in the X-direction. One write transistor Wtr may be selected by appropriate voltages conveyed by one write word line WWL and one write bit line WBL. One read transistor Rtr may be selected by appropriate voltages conveyed by one read word line RWL and one read bit line RBL.

According to embodiments, since memory cells MC1, MC2, MC3, MC4, MC5, and MC6, adjacent in the X-direction, may share the write bit line WBL or the read bit line RBL, a size of a semiconductor device in the X-direction may decrease and a degree of integration of the memory cells may increase. For example, the first memory cell MC1 and the second memory cell MC2 may share the write bit line WBL, and the second memory cell MC2 and the third memory cell MC3 may share the read bit line RBL.

According to embodiments, memory cells MC1, MC2, MC3, MC4, MC5, and MC6, adjacent in the X-direction, may be disposed symmetrically with respect to the write bit line WBL or the read bit line RBL. For example, the write transistors Wtr and the read transistors Rtr of the first memory cell MC1 and the second memory cell MC2 may be disposed symmetrically with respect to an axis vertically penetrating the write bit line WBL. The write transistors Wtr and the read transistors Rtr of the second memory cell MC2 and the third memory cell MC3 may be disposed symmetrically with respect to the read bit line RBL.

The write transistor Wtr may store charges in the storage node SN. Depending on amounts of charges stored in the storage node SN, a threshold voltage of the read transistor Rtr in which the storage node SN functions as a gate may be changed. Depending on the threshold voltage of the read transistor Rtr, data stored in the memory cell may be read as ‘0’ or ‘1.’

In the write operation, a programming voltage Vpgm may be applied to the write bit line WBL, and a boost voltage Vpp may be applied to the write word line WWL, to store charges in the storage node SN. A second write control voltage may be applied to the read word line RWL and the read bit line RBL, and the second write control voltage may be a ground voltage GND.

In the read operation, a read voltage Vread may be applied to the read word line RWL, to read data from the read bit line RBL. A voltage different from that of the read word line RWL may be applied to the read bit line RBL, for example, a ground voltage GND may be applied. The ground voltage GND may be applied to the write bit line WBL, and a negative voltage Vbb2 may be applied to the write word line WWL.

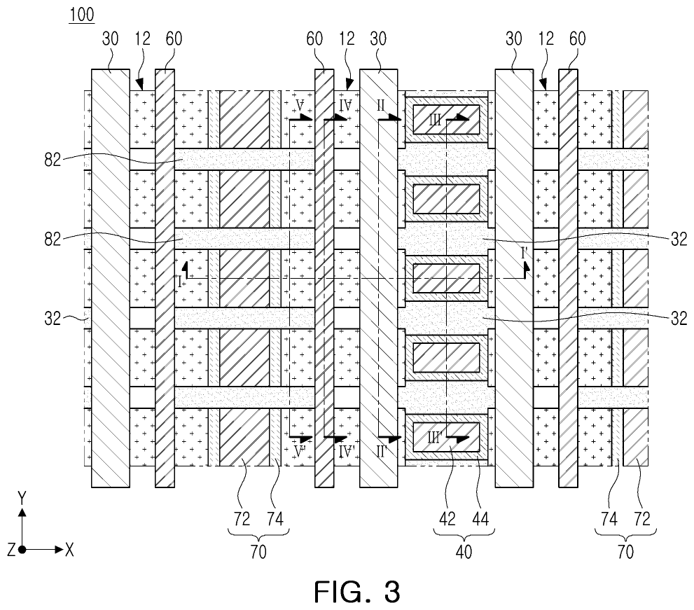

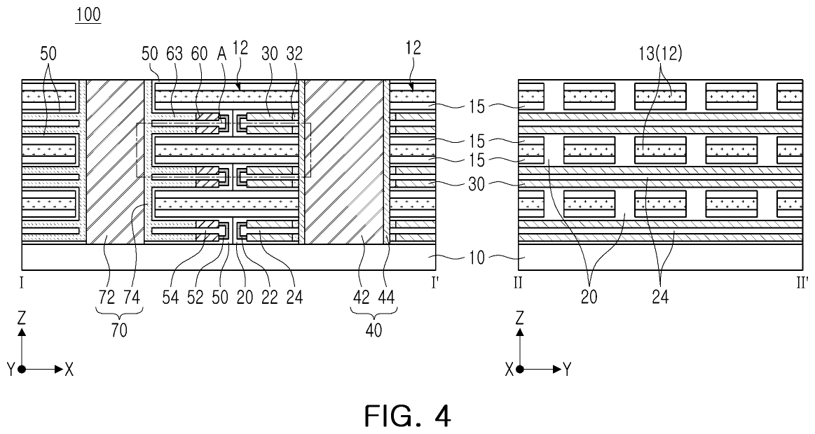

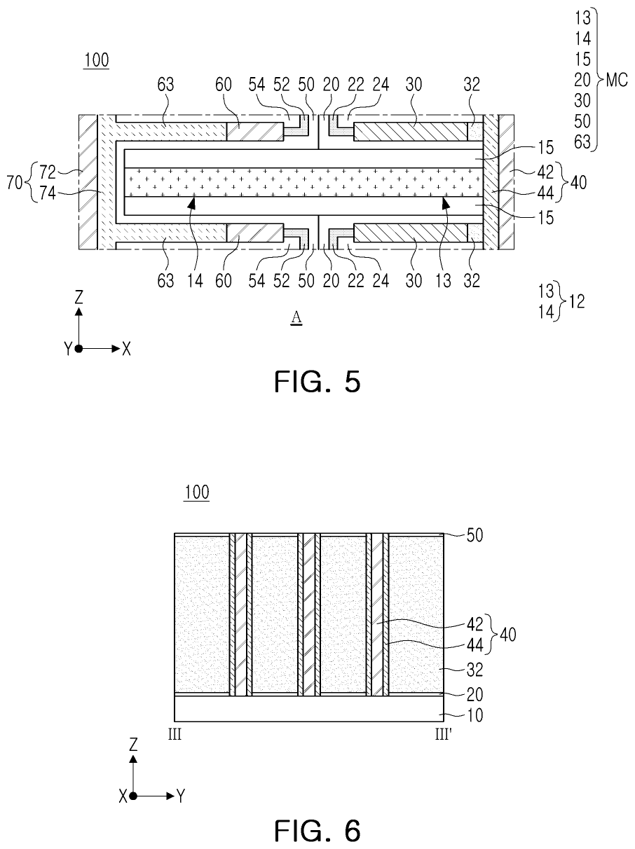

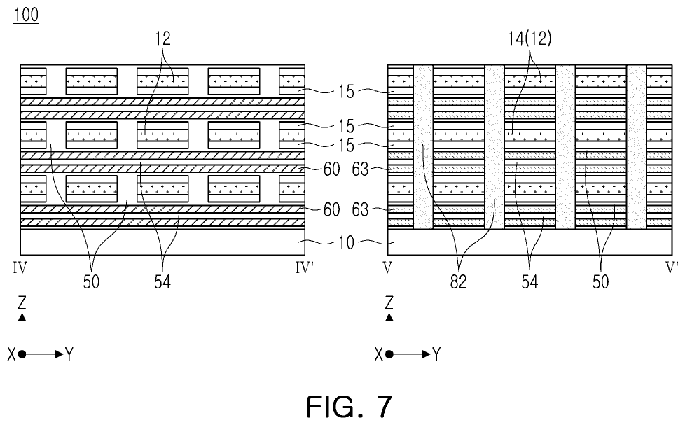

FIG. 3 is a plan view of a semiconductor device according to an example embodiment. FIG. 4 is a vertical cross-sectional view taken along lines I-I′ and II-II′ of the semiconductor device illustrated in FIG. 3. FIG. 5 is an enlarged view of a portion of the semiconductor device illustrated in FIG. 4. FIG. 5 may correspond to region A in the semiconductor device of FIG. 4. FIG. 6 is a vertical cross-sectional view taken along line III-III′ of the semiconductor device illustrated in FIG. 3. FIG. 7 is a vertical cross-sectional view taken along lines IV-IV′ and V-V′ of the semiconductor device illustrated in FIG. 3.

Referring to FIGS. 3 to 7, a semiconductor device 100 according to an embodiment may include a semiconductor material layer 12, a dielectric layer 15, a first gate dielectric pattern 20, a first word line 30, a first bit line 40, a second gate dielectric pattern 50, a second word line 60, a second channel region 63, and a second bit line 70, disposed on a substrate 10. The first word line 30 may be a word line used for a write operation, and may be referred to as a write word line 30. The first bit line 40 may be a bit line used for the write operation, and may be referred to as a write bit line 40. The second word line 60 may be a word line used for a read operation, and may be referred to as a read word line 60. The second bit line 70 may be a bit line used for the read operation, and may be referred to as a read bit line 70.

A portion of the semiconductor material layer 12 overlapping the write word line 30 in the vertical direction may be referred to as a first channel region 13, and a portion of the semiconductor material layer 12 overlapping the second channel region 63 in the vertical direction may be referred to as a charge storage region 14. As used herein, “an element A overlapping an element B in a direction X” (or similar language) means that there is at least one line that extends in the direction X and intersects both the elements A and B.

The write transistor Wtr described with reference to FIGS. 1 and 2 may include the first channel region 13. The first channel region 13 may be electrically connected to the write word line 30. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items. The first channel region 13 may correspond to the channel CH1 of FIG. 2, and the write word line 30 may correspond to the write word line WWL. A portion in which the write word line 30 overlaps the first channel region 13 in the vertical direction may function as a gate of the write transistor Wtr. A portion of the dielectric layer 15 between the first channel region 13 and the write word line 30, and a portion of the first gate dielectric pattern 20 may be included in the write transistor Wtr.

The read transistor Rtr described with reference to FIGS. 1 and 2 may include the second channel region 63. The second channel region 63 may be electrically connected to the read word line 60. The second channel region 63 may correspond to the channel CH2 of FIG. 2, and the read word line 60 may correspond to the read word line RWL. The charge storage region 14 may be electrically connected to the first channel region 13, and may include the storage node SN described with reference to FIGS. 1 and 2. The charge storage region 14 may also function as a gate of the read transistor Rtr. A portion of the dielectric layer 15 between the second channel region 63 and the charge storage region 14, and a portion of the second gate dielectric pattern 50 may be included in the read transistor Rtr.

The first channel region 13, the write word line 30, the dielectric layer 15, the first gate dielectric pattern 20, the second channel region 63, the charge storage region 14, and the second gate dielectric pattern 50 may constitute a memory cell MC. For example, FIG. 5 illustrates components of the memory cell MC. Memory cells MC may have a structure identical to or similar to the memory cells MC1, MC2, MC3, MC4, MC5, and MC6 described with reference to FIGS. 1 and 2.

The semiconductor material layers 12 may extend in the X-direction, and may be spaced apart from each other in the X-direction, the Y-direction, and the Z-direction. The semiconductor material layers 12 may include at least one of a polycrystalline semiconductor material, an oxide semiconductor material such as indium gallium zinc oxide (IGZO) or the like, or a two-dimensional material such as molybdenum disulfide (MoS₂) or the like. In an embodiment, the semiconductor material layers 12 may include an oxide semiconductor material.

The oxide semiconductor material may be indium gallium zinc oxide (IGZO). However, an embodiment is not limited thereto. For example, the oxide semiconductor material may include at least one of indium tungsten oxide (IWO), indium tin gallium oxide (ITGO), indium aluminum zinc oxide (IAGO), indium gallium oxide (IGO), indium tin zinc oxide (ITZO), zinc tin oxide (ZTO), indium zinc oxide (IZO), ZnO, indium gallium silicon oxide (IGSO), indium oxide (InO), tin oxide (SnO), titanium oxide (TiO), zinc oxynitride (ZnON), magnesium zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), or indium gallium silicon oxide (InGaSiO).

The two-dimensional material may include at least one of a transition metal dichalcogenide (TMD) material layer, a black phosphorous material layer, or a hexagonal boron-nitride (hBN) material layer, having semiconductor properties. For example, the two-dimensional material may include at least one of BiOSe, Crl, WSe₂, MoS₂, TaS, WS, SnSe, ReS, β-SnTe, MnO, AsS, P(black), InSe, h-BN, GaSe, GaN, SrTiO, MXene, or a Janus 2D material, which may form a two-dimensional material.

As described above, each of the semiconductor material layers 12 may include the first channel region 13 and the charge storage region 14. At least a portion of the first channel region 13 may be disposed on the same level, in the Z-direction, as the charge storage region 14. For example, the first channel region 13 may have the same cross-sectional thickness as the charge storage region 14, and upper and lower surfaces of the first channel region 13 may be coplanar with upper and lower surfaces of the charge storage region 14, respectively. In an embodiment, the first channel region 13 may include the same material as the charge storage region 14, and may be formed integrally. A boundary between the first channel region 13 and the charge storage region 14 may not be observed. The first channel regions 13 of the respective the semiconductor material layers 12 may overlap the write word lines 30 in the vertical direction, and the charge storage regions 14 of the respective the semiconductor material layers 12 may overlap the second channel regions 63 in the vertical direction.

In an embodiment, a carrier density and electrical conductivity of the charge storage region 14 may be greater than those of the first channel region 13. For example, the semiconductor material layer 12 may include an oxide semiconductor material, and a concentration of an oxygen vacancy in the charge storage region 14 may be greater than those of the first channel region 13. In an embodiment, the charge storage region 14 may be doped with impurities to increase electrical conductivity, and for example, the impurities may include fluorine (F).

The dielectric layers 15 may cover at least one of upper and lower surfaces of the semiconductor material layers 12, and may extend in the horizontal direction. For example, both the first channel region 13 and the charge storage region 14 may be covered by the dielectric layer 15. The dielectric layers 15 may overlap the semiconductor material layers 12 in the vertical direction, and side surfaces of the semiconductor material layers 12 may be coplanar with side surfaces of the dielectric layers 15. The dielectric layers 15 may protect the semiconductor material layers 12 during a manufacturing process, and may also function as a gate dielectric layer of the write transistor Wtr or the read transistor Rtr. Each of the dielectric layers 15 may include at least one of silicon oxide or a high-κ dielectric. For example, the high-κ dielectric may be formed of, but is not limited to, HfO₂, HfSiO, HfSiON, HfTaO, HfTiO, HfZrO, ZrO₂, Al₂O₃, or a combination thereof. Each of the gate dielectric layers 15 may be formed as a single layer or multiple layers of the materials mentioned above.

The write word lines 30 may extend in the Y-direction, and may be spaced apart from each other in the X-direction and the vertical direction (Z-direction). For example, two write word lines 30 may be spaced apart from each other in the vertical direction between two adjacent semiconductor material layers 12 in the vertical direction. An X-direction length of the write word lines 30 may be less than an X-direction length of the semiconductor material layers 12. The write word lines 30 may overlap the first channel regions 13 of the semiconductor material layers 12 in the vertical direction. The write word lines 30 may be disposed in a double gate structure. For example, for each of the first channel regions 13, one write word line 30 may be disposed above and below the first channel regions 13. Since the write word lines 30 may be disposed in a double gate structure, an amount of current flowing in the first channel regions 13 may increase. In addition, between adjacent memory cells MC in the vertical direction, electrical coupling of write word lines 30 constituting different memory cells MC may be prevented or reduced.

According to an embodiment, the write word lines 30 may be disposed in a gate-all-around (GAA) structure surrounding the first channel regions 13. The term “surrounding” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles.

The write word lines 30 may include doped polysilicon, metal, a conductive metal nitride, a metal-semiconductor compound, a metal compound, a conductive metal oxide, graphene, a carbon nanotube, or a combination thereof. For example, at least one of the write word lines 30 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, a carbon nanotube, or a combination thereof.

The semiconductor device 100 may further include a first insulating layer 22 and a second insulating layer 24. The first gate dielectric pattern 20, the first insulating layer 22, and the second insulating layer 24 may be disposed between two adjacent semiconductor material layers 12 in the vertical direction, and may be in contact with the write word line 30. For example, the first gate dielectric pattern 20 may include horizontal portions extending in the horizontal direction while being in contact with the dielectric layers 15, and a vertical portion extending in the vertical direction from one end of the horizontal portions. As illustrated in FIG. 5, in a cross-sectional view, the first gate dielectric pattern 20 may have a U-shape with an opening facing in the X-direction. As illustrated in FIG. 6, the first gate dielectric pattern 20 may cover an upper surface of the substrate 10. The second insulating layer 24 may be disposed between two adjacent write word lines 30 in the vertical direction, and may extend in the Y-direction. The first insulating layer 22 may extend between the first gate dielectric pattern 20 and the second insulating layer 24, and may be in contact with the write word lines 30. In a cross-sectional view, the first insulating layer 22 may have a U-shape with an opening facing in the X-direction.

The first gate dielectric pattern 20 may include at least one of silicon oxide or high-κ dielectric. The first insulating layer 22 and the second insulating layer 24 may include silicon oxide, silicon nitride, silicon oxynitride, silicon carbonitride, a low-κ dielectric, or a combination thereof. The first insulating layer 22 may include a material having etching selectivity with respect to the second insulating layer 24. For example, the first insulating layer 22 may include silicon nitride, and the second insulating layer 24 may include silicon oxide.

The write bit lines 40 may extend in the vertical direction, and may be spaced apart from each other in the Y-direction. The write bit lines 40 may be in contact with and be electrically connected to semiconductor material layers 12 spaced apart in the vertical direction. For example, the write bit lines 40 may be disposed between semiconductor material layers 12 adjacent in the X-direction.

In an embodiment, each of the write bit lines 40 may include a first conductive layer 42 and a first liner layer 44. The first conductive layer 42 may extend in the vertical direction, and may have a pillar shape. In plan view, the first conductive layer 42 is illustrated as being rectangular, but is not limited thereto. According to an embodiment, the first conductive layer 42 may have a circular shape or an elliptical shape. The first liner layer 44 may surround (i.e., extend around) the first conductive layer 42, and may extend in the horizontal direction along a side surface of the first conductive layer 42. The first liner layer 44 may be in contact with and be electrically connected to the first channel regions 13 spaced apart in the vertical direction. According to an embodiment, the first liner layer 44 may extend further in the horizontal direction to cover a lower surface of the first conductive layer 42.

The first conductive layer 42 may include doped polysilicon, metal, a conductive metal nitride, a metal-semiconductor compound, a metal compound, a conductive metal oxide, graphene, a carbon nanotube, or a combination thereof. The first liner layer 44 may include an oxide semiconductor material. In an embodiment, the first liner layer 44 may include the same material as the semiconductor material layer 12, for example, IGZO. In some embodiments, the semiconductor material layer 12 and the first liner layer 44 may include different oxide semiconductor materials. In an embodiment, a carrier density and electrical conductivity of the first liner layer 44 may be greater than those of the first channel region 13. For example, a concentration of an oxygen vacancy in the first liner layer 44 may be greater than that of the first channel region 13. In an embodiment, an indium (In) concentration of the first liner layer 44 may be higher than an indium (In) concentration of the first channel region 13.

The semiconductor device 100 may further include a capping layer 32. The capping layer 32 may be between the write word lines 30 and the write bit lines 40 and between write bit lines 40 spaced apart in the Y-direction. The capping layer 32 may electrically insulate the write word lines 30 and the write bit lines 40. The capping layer 32 may include silicon oxide, silicon nitride, silicon oxynitride, silicon carbonitride, a low-κ dielectric, or a combination thereof.

The second channel regions 63 may extend in the Y-direction, and may be spaced apart from each other in the X-direction and the vertical direction. For example, two second channel regions 63 may be disposed spaced apart in the vertical direction between two adjacent semiconductor material layers 12 in the vertical direction. An X-direction length of the second channel regions 63 may be less than an X-direction length of the semiconductor material layers 12. The second channel regions 63 may be disposed adjacent to the charge storage regions 14 of the semiconductor material layers 12. For example, the second channel regions 63 may overlap the charge storage regions 14 of the semiconductor material layers 12 in the vertical direction. The second channel regions 63 may be disposed in a double channel structure. For example, for each charge storage region 14, one second channel region 63 may be disposed above and below the charge storage regions 14. Since the second channel regions 63 may be disposed in a double channel structure, an amount of current flowing in the charge storage regions 14 may increase. In addition, between adjacent memory cells MC in the vertical direction, the second channel regions 63 and the charge storage regions 14 constituting different memory cells MC may be prevented or reduced from being electrically coupled.

According to an embodiment, the second channel regions 63 may be disposed in a channel-all-around structure surrounding the charge storage regions 14. At least a portion of the second channel region 63 may be disposed on the same level as the write word line 30 in the Z-direction. In an embodiment, upper and lower surfaces of the second channel region 63 may be coplanar with upper and lower surfaces of the write word line 30, respectively. The second channel region 63 may have the same vertical thickness as the write word line 30, but is not limited thereto.

The second channel regions 63 may include at least one of a polycrystalline semiconductor material layer, an oxide semiconductor material such as IGZO or the like, or a two-dimensional material such as MoS₂ or the like. In an embodiment, the second channel regions 63 may include an oxide semiconductor material.

The read word lines 60 may extend in the Y-direction, and may be spaced apart from each other in the X-direction and the vertical direction (Z-direction). The read word lines 60 may be disposed between the write word lines 30 and the second channel regions 63. For example, two read word lines 60 may be spaced apart from each other in the vertical direction between two adjacent semiconductor material layers 12 in the vertical direction. The read word lines 60 may be in contact with end portions of the second channel regions 63, and may be spaced apart from the write word lines 30 in the X-direction. According to an embodiment, the read word lines 60 may be disposed in a gate-all-around structure surrounding the charge storage regions 14. At least a portion of the read word line 60 may be disposed on the same level as the write word line 30 and the second channel region 63. In an embodiment, upper and lower surfaces of the read word line 60 may be coplanar with upper and lower surfaces of the write word line 30, respectively. The read word line 60 may have the same vertical thickness as the write word line 30 and the second channel region 63, but is not limited thereto.

The read word lines 60 may include doped polysilicon, metal, a conductive metal nitride, a metal-semiconductor compound, a metal compound, a conductive metal oxide, graphene, a carbon nanotube, or a combination thereof.

The semiconductor device 100 may further include a third insulating layer 52 and a fourth insulating layer 54. The second gate dielectric pattern 50 may extend between the dielectric layers 15 and the read word lines 60, and between the dielectric layers 15 and the second channel regions 63 in the horizontal direction. The second gate dielectric pattern 50 may also extend between the dielectric layers 15 and the read bit line 70 and between the charge storage regions 14 and the read bit line 70 in the vertical direction. The second gate dielectric pattern 50 may also be in contact with the first gate dielectric patterns 20, and may extend in the vertical direction. The second gate dielectric pattern 50 may cover an upper surface of an uppermost dielectric layer 15.

In an embodiment, a portion of the second gate dielectric pattern 50 may be formed integrally with the first gate dielectric pattern 20. For example, a portion of the second gate dielectric pattern 50 covering the upper surface of the uppermost dielectric layer 15 may be formed integrally with the first gate dielectric pattern 20.

The fourth insulating layer 54 may be disposed between two adjacent read word lines 30 in the vertical direction and between the second channel regions 63, and may extend in the Y-direction. The third insulating layer 52 may extend between the second gate dielectric pattern 50 and the fourth insulating layer 54, and may be in contact with the read word lines 60. In a cross-section, the third insulating layer 52 may have a U-shape with an opening facing the X-direction.

The second gate dielectric pattern 50 may include at least one of silicon oxide or a high-κ dielectric.

In another example, each of the first gate dielectric pattern 20 and the second gate dielectric pattern 50 may include a data storage layer and a dielectric layer. For example, each of the first gate dielectric pattern 20 and the second gate dielectric pattern 50 may include a ferroelectric layer that may have polarization characteristics depending on an electric field, and may have remnant polarization by a dipole even in the absence of an external electric field. Data may be recorded using a polarization state within the ferroelectric layer. Therefore, each of the first gate dielectric pattern 20 and the second gate dielectric pattern 50 may include a ferroelectric layer that may be referred to as a data storage layer. The ferroelectric layer, which may be the data storage layer, may include a Hf-based compound, a Zr-based compound, and/or a Hf-Zr-based compound. For example, the Hf-based compound may be a HfO-based ferroelectric material, the Zr-based compound may include a ZrO-based ferroelectric material, and the Hf-Zr-based compound may include a hafnium zirconium oxide (HZO)-based ferroelectric material. The ferroelectric layer, which may be the data storage layer, may include a ferroelectric material doped with an impurity, for example, at least one of C, Si, Mg, Al, Y, N, Ge, Sn, Gd, La, Sc, or Sr. For example, the ferroelectric layer, which may be the data storage layer, may be a material in which at least one of an impurity, C, Si, Mg, Al, Y, N, Ge, Sn, Gd, La, Sc, or Sr is doped with at least one of HfO₂, ZrO₂, or HZrO.

In the first gate dielectric pattern 20 and the second gate dielectric pattern 50, the data storage layer is not limited to types of materials described above, and may include a material capable of storing data.

The third insulating layer 52 and the fourth insulating layer 54 may include silicon oxide, silicon nitride, silicon oxynitride, silicon carbonitride, a low-κ dielectric, or a combination thereof. The third insulating layer 52 may include a material having etching selectivity with respect to the fourth insulating layer 54. For example, the third insulating layer 52 may include silicon nitride, and the fourth insulating layer 54 may include silicon oxide.

The read bit lines 70 may extend in the vertical direction, and may be spaced apart from each other in the Y-direction. The read bit lines 70 may be in contact with and electrically connected to the second channel regions 63 spaced apart in the vertical direction. For example, the read bit lines 70 may be between adjacent semiconductor material layers 12 in the X-direction. The write bit lines 40 and the read bit lines 70 may be disposed alternately in the X-direction.

In an embodiment, each of the read bit lines 70 may include a second conductive layer 72 and a second liner layer 74. The second conductive layer 72 may extend in the vertical direction, and may have a pillar shape. In plan view, the second conductive layer 72 is illustrated as being rectangular, but is not limited thereto. According to an embodiment, the second conductive layer 72 may have a circular shape or an elliptical shape. The second liner layer 74 may surround the second conductive layer 72, and may extend in the horizontal direction along a side surface of the second conductive layer 72. The second liner layer 74 may be in contact with and be electrically connected to the second channel regions 63 spaced apart in the vertical direction. For example, the second liner layer 74 may include the same material as the second channel regions 63, and may be formed integrally. The second liner layer 74 may be spaced apart from the semiconductor material layer 12 and the dielectric layer 15 with the second gate dielectric pattern 50 interposed therebetween. According to an embodiment, the second liner layer 74 may extend further in the horizontal direction to cover a lower surface of the second conductive layer 72.

The second conductive layer 72 may include doped polysilicon, metal, a conductive metal nitride, a metal-semiconductor compound, a metal compound, a conductive metal oxide, graphene, a carbon nanotube, or a combination thereof. The second liner layer 74 may include an oxide semiconductor material. In an embodiment, the second liner layer 74 may include the same material as the second channel region 63, for example, IGZO. According to an embodiment, the second channel region 63 and the second liner layer 74 may include different oxide semiconductor materials, and the second liner layer 74 may be formed in a separate process from the second channel region 63. In an embodiment, a carrier density and electrical conductivity of the second liner layer 74 may be greater than those of the second channel region 63. For example, a concentration of an oxygen vacancy in the second liner layer 74 may be greater than those in the second channel region 63.

The semiconductor device 100 may further include spacer patterns 82. The spacer patterns 82 may be disposed between read bit lines 70 spaced apart in the Y-direction. The spacer patterns 82 may electrically insulate the write bit lines 40. As illustrated in FIG. 3, the spacer patterns 82 may extend in the X-direction, and may be in contact with the read word lines 60. The spacer patterns 82 may include silicon oxide, silicon nitride, silicon oxynitride, silicon carbonitride, a low-κ dielectric, or a combination thereof.

According to embodiments, adjacent memory cells MC in the X-direction may share the write bit line 40 or the read bit line 70. For example, in the cross-sectional view illustrated in FIG. 4, the write bit line 40 may be electrically connected to first channel regions 13 spaced apart from each other in the X-direction, and the first channel regions 13 spaced apart from each other may be components of different memory cells MC. The read bit line 70 may be electrically connected to second channel regions 63 spaced apart from each other in the X-direction, and the second channel regions 63 spaced apart from each other may be components of different memory cells MC. Since the adjacent memory cells MC share the write bit line 40 or the read bit line 70, a size of the semiconductor device in the X-direction may decrease, and a degree of integration of the memory cells MC may increase.

According to an embodiment, only one of the write bit lines 40 or the read bit lines 70 may be shared between the memory cells MC. For example, the write bit lines 40 may not be shared, and two write bit lines 40 may be disposed between adjacent memory cells MC in the X-direction. Alternatively, the read bit lines 70 may not be shared, and two read bit lines 70 may be disposed between adjacent memory cells MC in the X-direction.

According to embodiments, adjacent memory cells MC in the X-direction may be disposed symmetrically (e.g., mirror-symmetrically) with respect to the write bit line 40 or the read bit line 70. For example, as illustrated in FIGS. 3 and 4, with respect to an axis passing through the write bit line 40 and extending in the vertical direction, the first channel regions 13, the charge storage regions 14, the write word lines 30, the read word lines 60, and the read bit lines 70 may be symmetrically disposed. With respect to an axis passing through the read bit line 70 and extending in the vertical direction, the first channel regions 13, the charge storage regions 14, the write word lines 30, the write bit lines 40, and the read word lines 60 may be symmetrically disposed.

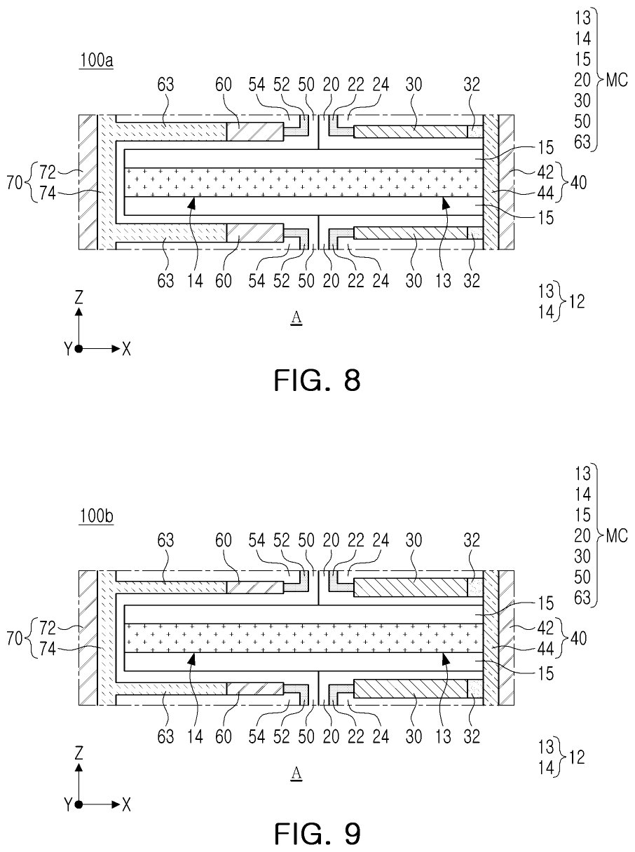

FIGS. 8 and 9 are vertical cross-sectional views of semiconductor devices according to example embodiments.

Referring to FIG. 8, a semiconductor device 100a may include a write word line 30 overlapping a first channel region 13 in the vertical direction, and a second channel region 63 overlapping a charge storage region 14 in the vertical direction. In an embodiment, a vertical thickness of the write word line 30 and a vertical thickness of the second channel region 63 may be different. For example, the vertical thickness of the write word line 30 may be less than the vertical thickness of the second channel region 63. A vertical thickness of a read word line 60 may be the same as the vertical thickness of the second channel region 63, and may be greater than the vertical thickness of the write word line 30.

Referring to FIG. 9, a semiconductor device 100b may include a write word line 30 overlapping a first channel region 13 in the vertical direction, and a second channel region 63 overlapping a charge storage region 14 in the vertical direction. In an embodiment, a vertical thickness of the write word line 30 and a vertical thickness of the second channel region 63 may be different. For example, the vertical thickness of the write word line 30 may be greater than the vertical thickness of the second channel region 63. A vertical thickness of a read word line 60 may be the same as the vertical thickness of the second channel region 63, and may be less than the vertical thickness of the write word line 30.

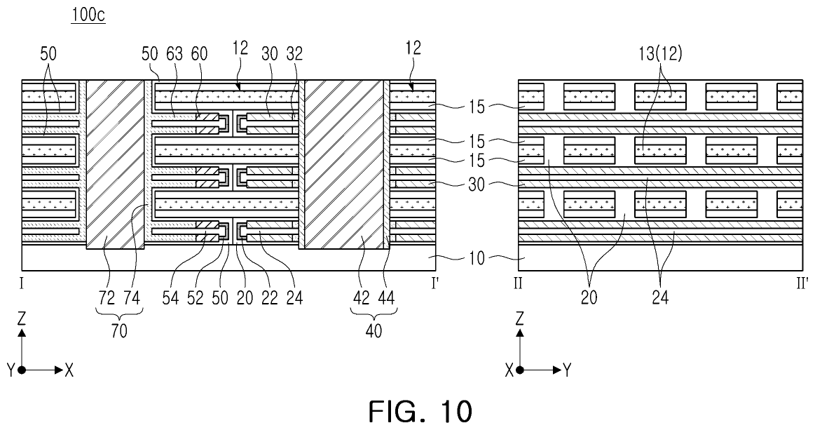

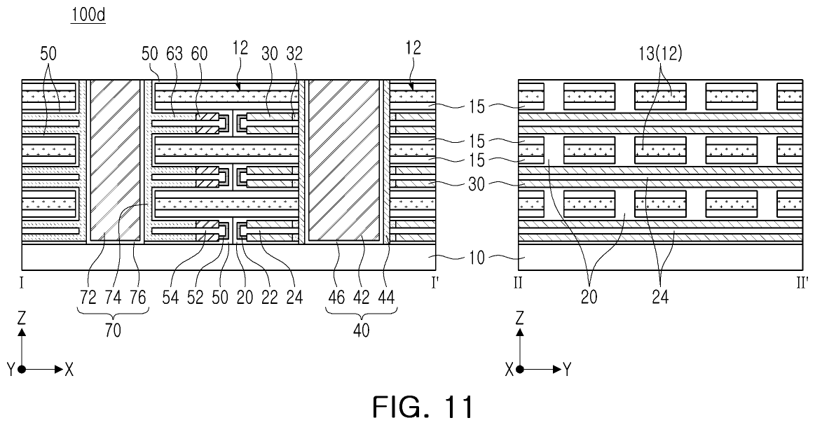

FIGS. 10 and 11 are vertical cross-sectional views of semiconductor devices according to example embodiments.

Referring to FIG. 10, a semiconductor device 100c may include a write bit line 40 and a read bit line 70, disposed between semiconductor material layers 12 spaced apart in the X-direction. In an embodiment, a lower surface of the write bit line 40 and a lower surface of the read bit line 70 may be disposed on a lower level than an upper end (i.e., surface) of a substrate 10 in the vertical direction (Z-direction). For example, the write bit line 40 may pass through a first gate dielectric pattern 20, and may partially extend into the substrate 10. The read bit line 70 may pass through a second gate dielectric pattern, and may partially extend into the substrate 10.

Referring to FIG. 11, a semiconductor device 100d may include a write bit line 40 and a read bit line 70, disposed between semiconductor material layers 12 spaced apart in the X-direction. In an embodiment, the write bit line 40 may further include a first barrier layer 46 between a first conductive layer 42 and a first liner layer 44. The first barrier layer 46 may prevent a metal material included in the first conductive layer 42 from diffusing into the first liner layer 44. The first barrier layer 46 may cover a lower surface and side surfaces of the first conductive layer 42, and may have a U-shape. The term “cover” (or “covering,” or like terms), as may be used herein, is intended to broadly refer to an element, structure or layer that is on or over another element, structure or layer, either directly or with one or more other intervening elements, structures or layers therebetween. In an embodiment, the read bit line 70 may further include a second barrier layer 76 between a second conductive layer 72 and a second liner layer 74. The second barrier layer 76 may prevent a metal material included in the second conductive layer 72 from diffusing into the second liner layer 74. The second barrier layer 76 may cover a lower surface and side surfaces of the second conductive layer 72, and may have a U-shape.

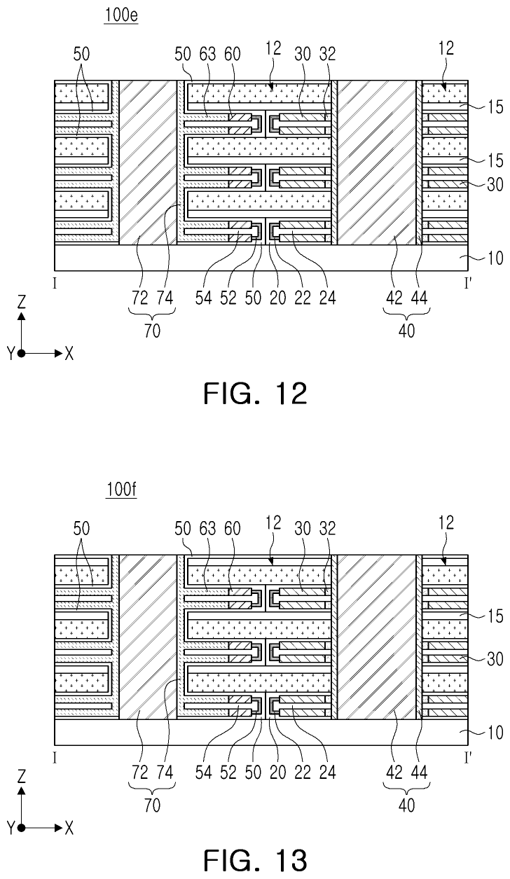

FIGS. 12 to 14 are vertical cross-sectional views of semiconductor devices according to example embodiments.

Referring to FIG. 12, a semiconductor device 100e may include semiconductor material layers 12 and dielectric layers 15 covering the semiconductor material layers 12. In an embodiment, the dielectric layers 15 may be disposed only on an upper surface or a lower surface of each of the semiconductor material layers 12. For example, the dielectric layers 15 may cover the lower surface of each of the semiconductor material layers 12. The upper surface of each of the semiconductor material layers 12 may be in contact with a first gate dielectric pattern 20 and a second gate dielectric pattern 50. In an embodiment, distances between a semiconductor material layer 12 and two write word lines 30 adjacent thereto in the vertical direction may be different. For example, the semiconductor material layer 12 may be disposed closer to a write word line 30 located on a relatively higher level, among the two adjacent write word lines 30 in the vertical direction. In an embodiment, distances between the semiconductor material layer 12 and two second channel regions 63 adjacent thereto in the vertical direction may be different. For example, the semiconductor material layer 12 may be disposed closer to a second channel region 63 located on a relatively higher level, among the two adjacent second channel regions 63 in the vertical direction.

Referring to FIG. 13, a semiconductor device 100f may include semiconductor material layers 12 and dielectric layers 15 on the semiconductor material layers 12. In an embodiment, the dielectric layers 15 may be disposed only on an upper surface or a lower surface of each of the semiconductor material layers 12. For example, the dielectric layers 15 may cover the upper surface of each of the semiconductor material layers 12. The lower surface of each of the semiconductor material layers 12 may be in contact with a first gate dielectric pattern 20 and a second gate dielectric pattern 50. In an embodiment, distances between a semiconductor material layer 12 and two write word lines 30 adjacent thereto in the vertical direction may be different. For example, the semiconductor material layer 12 may be disposed closer to a write word line 30 located on a relatively lower level, among the two adjacent write word lines 30 in the vertical direction. In an embodiment, distances between the semiconductor material layer 12 and two second channel regions 63 adjacent thereto in the vertical direction may be different. For example, the semiconductor material layer 12 may be disposed closer to a second channel region 63 located on a relatively lower level, among the two adjacent second channel regions 63 in the vertical direction.

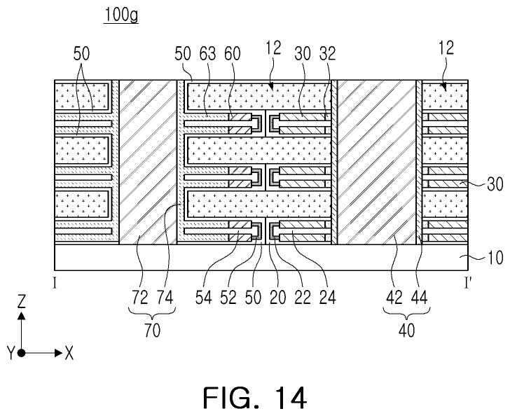

Referring to FIG. 14, unlike the semiconductor device 100 illustrated in FIG. 4, dielectric layers 15 may be omitted in a semiconductor device 100g. For example, an upper surface or a lower surface of each of semiconductor material layers 12 may be in contact with a first gate dielectric pattern 20 and a second gate dielectric pattern 50.

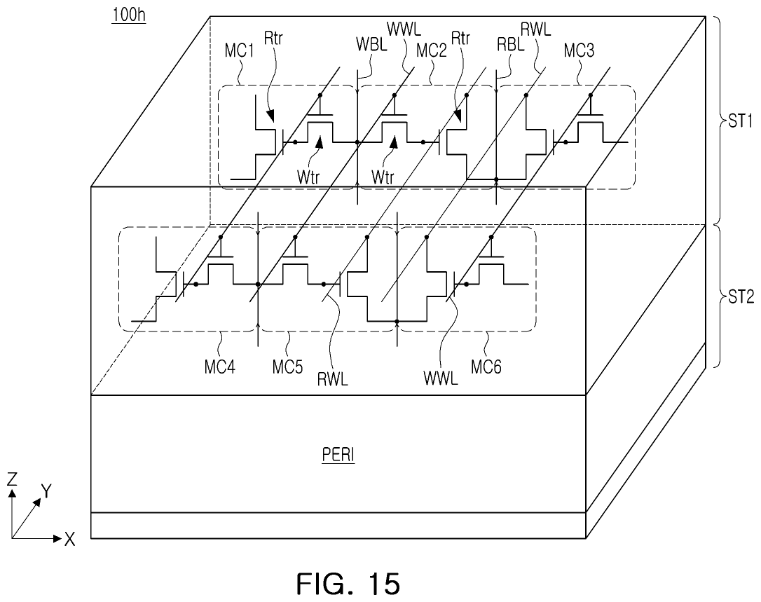

FIG. 15 is a conceptual perspective view of a semiconductor device according to an example embodiment.

Referring to FIG. 15, a semiconductor device 100h may include a first structure ST1 and a second structure ST2 below the first structure ST1 in the vertical direction. The first structure ST1 may include memory cells MC of the semiconductor devices 100, 100a, 100b, 100c, 100d, 100e, 100f, and 100g described with reference to FIGS. 1 to 14.

The second structure ST2 may include a peripheral circuit region PERI, and the peripheral circuit region PERI may include a peripheral circuit element including a peripheral transistor. For example, logic elements such as an inverter circuit, a NAND gate circuit, a NOR gate circuit, an AND gate circuit, an OR gate circuit, an XOR gate circuit, an XNOR gate circuit, a NOT gate circuit, an antifuse, or the like may be disposed in the peripheral circuit region PERI. The peripheral circuit region PERI may also include peripheral circuits such as a sense amplifier, a sub-word line driver, or the like used for an operation of the memory cells MC, and peripheral circuits for input/output of data or commands, or input of power/ground.

In an embodiment, the second structure ST2 may be joined to the first structure ST1. For example, the first structure ST1 may include first bonding pads on a lower surface, and the second structure ST2 may include second bonding pads bonded to the first bonding pads on an upper surface of the second structure ST2. The first bonding pads and the second bonding pads may electrically connect the first structure ST1 and the second structure ST2.

In an embodiment, the semiconductor device 100h may include a connection plug penetrating (i.e., extending in or through) a joining surface between the first structure ST1 and the second structure ST2. The connection plug may electrically connect the first structure ST1 and the second structure ST2.

In an embodiment, the second structure ST2 may be disposed on the first structure ST1.

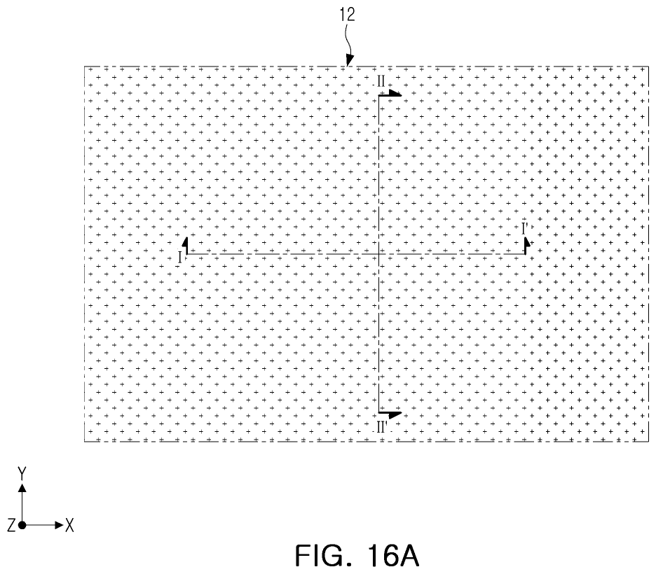

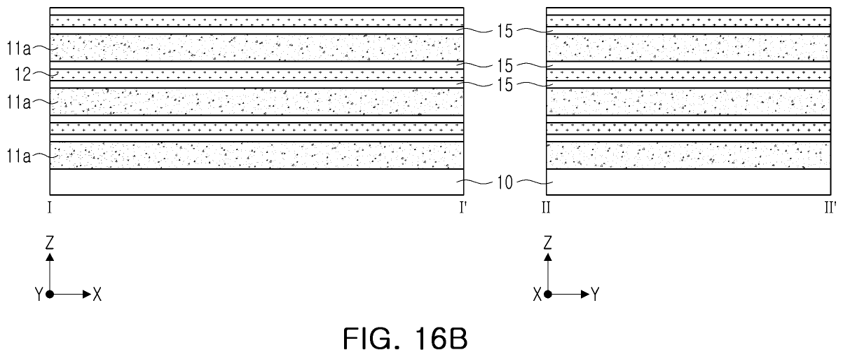

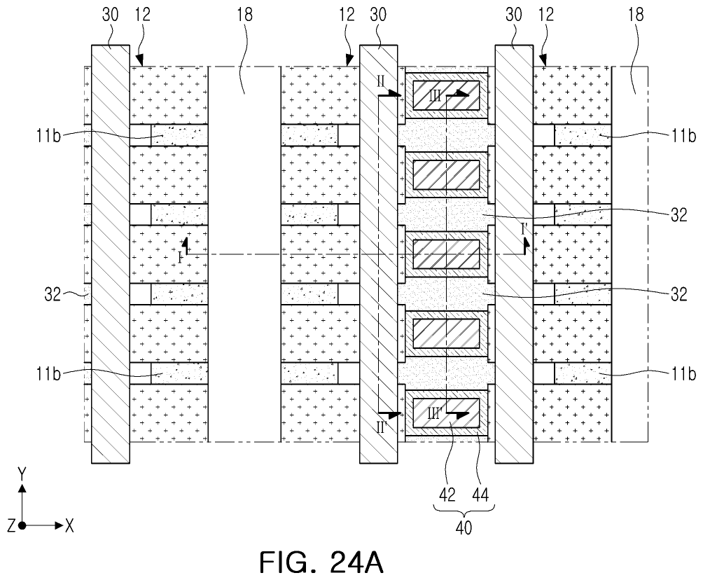

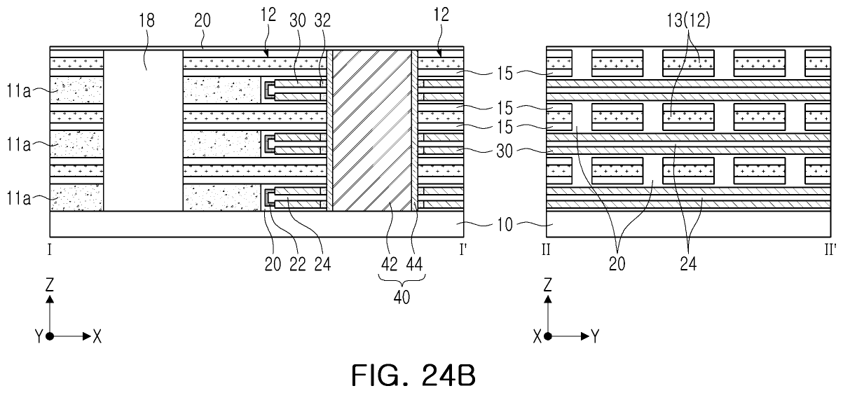

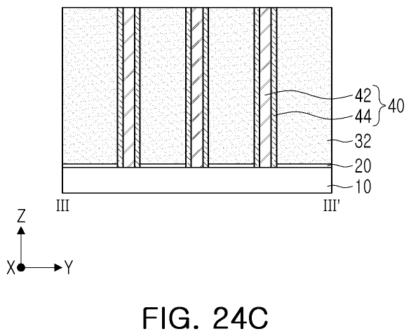

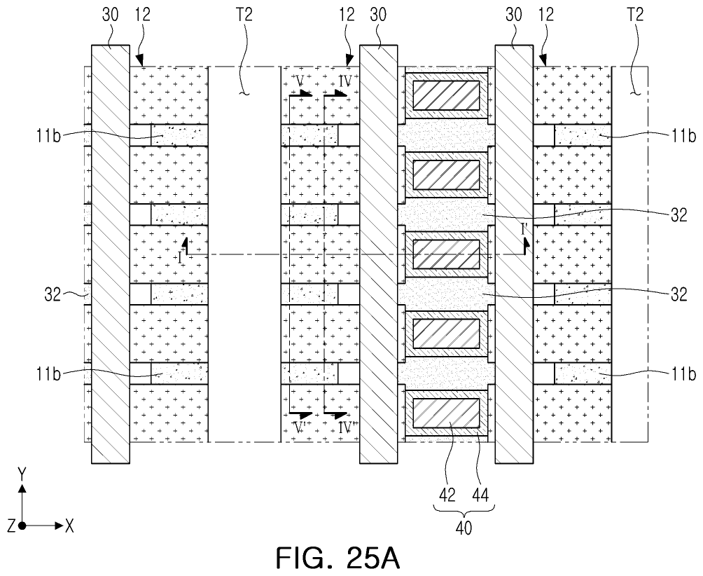

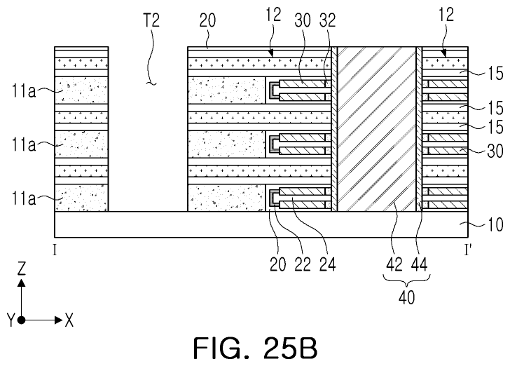

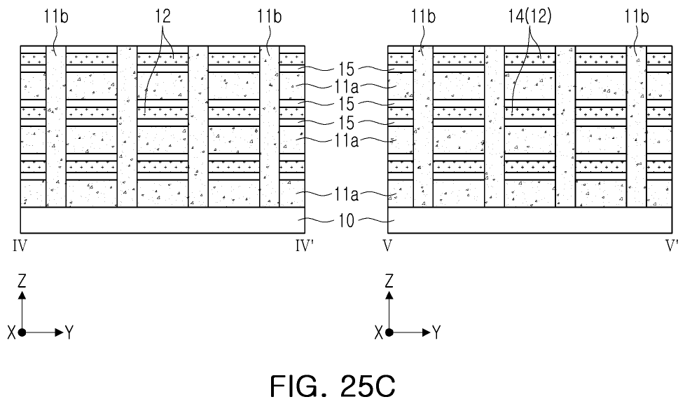

FIGS. 16A to 30C are plan views and vertical cross-sectional views illustrating a process sequence of intermediate processes in a method of manufacturing a semiconductor device according to an example embodiment. Specifically, FIGS. 16A, 17A, 18A, 19A, 22A, 23A, 24A, 25A, 26A, 28A, 29A, and 30A are plan views corresponding to FIG. 3. FIGS. 16B, 17B, 18B, 19B, 20, 21, 22B, 23B, 24B, 25B, 26B, 27A, 28B, 29B, and 30B are vertical cross-sectional views corresponding to FIG. 4. FIG. 24C is a vertical cross-sectional view corresponding to FIG. 6. FIGS. 25C, 26C, 27B, 28C, 29C, and 30C are vertical cross-sectional views corresponding to FIG. 7.

Referring to FIG. 16A and FIG. 16B, a stack structure (11a, 12, and 15) may be formed on a substrate 10. The stack structure may include a first sacrificial layer 11a, a semiconductor material layer 12, and a dielectric layer 15. A plurality of semiconductor material layers 12 may be spaced apart from each other in the vertical direction (Z-direction), and respective dielectric layers 15 may cover lower and upper surfaces of each of the semiconductor material layers 12. First sacrificial layers 11a may fill a space between the dielectric layers 15. For example, the first sacrificial layers 11a and the semiconductor material layers 12 may be disposed alternately in the vertical direction, and the dielectric layers 15 may be disposed between the first sacrificial layers 11a and the semiconductor material layers 12. The term “fill” (or “fills,” or like terms) is intended to refer to either completely filling a defined space (e.g., the space between the dielectric layers 15) or partially filling the defined space; that is, the defined space need not be entirely filled but may, for example, be partially filled or have voids or other spaces throughout.

The first sacrificial layer 11a may include a material having etching selectivity with respect to the semiconductor material layer 12 and the dielectric layer 15. The first sacrificial layer 11a may include silicon oxide, silicon nitride, silicon oxynitride, silicon carbonitride, a low-κ dielectric, or a combination thereof. For example, the first sacrificial layer 11a may include silicon nitride. The semiconductor material layer 12 may include a semiconductor material, and may include, for example, an oxide semiconductor material. The dielectric layer 15 may include a dielectric material, and may include, for example, AlO, but is not limited thereto.

According to an embodiment, for each of the semiconductor material layers 12, the dielectric layer 15 may not be formed on at least one of the upper and lower surfaces of the semiconductor material layer 12, and the semiconductor material layer 12 may be in contact with the first sacrificial layer 11a. For example, according to an embodiment, semiconductor devices 100e, 100f, and 100g illustrated in FIGS. 12 to 14 may be manufactured.

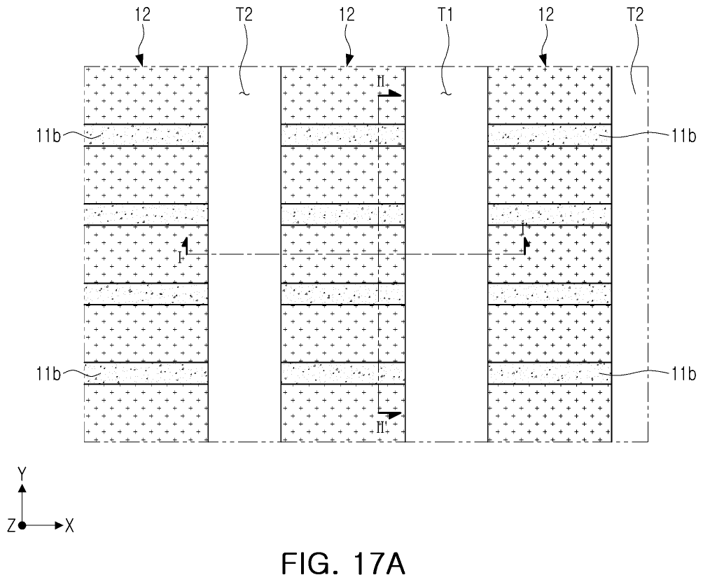

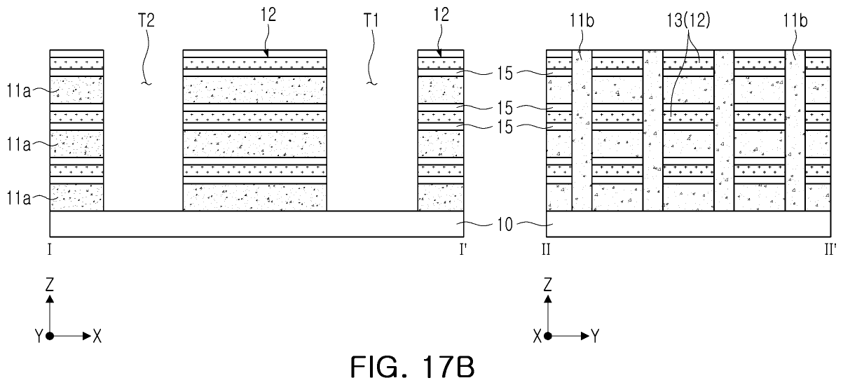

Referring to FIGS. 17A and 17B, second sacrificial layers 11b may be formed. The second sacrificial layers 11b may be formed by patterning the stack structure (11a, 12, and 15) by anisotropic etching, and then filling an insulating material therein. The second sacrificial layers 11b may extend in the X-direction and the Z-direction, and may be spaced apart from each other in the Y-direction. The second sacrificial layer 11b may include silicon oxide, silicon nitride, silicon oxynitride, silicon carbonitride, a low-κ dielectric, or a combination thereof. For example, the second sacrificial layer 11b may include the same material as the first sacrificial layer 11a, and may include, for example, silicon nitride.

After the second sacrificial layers 11b are formed, the stack structure (11a, 12, and 15) may be anisotropically etched to form first trenches T1 and second trenches T2. The first trenches T1 and the second trenches T2 may be alternately disposed in the X-direction. The first trenches T1 may be formed in positions corresponding to write bit lines 40, as illustrated in FIGS. 3 and 4, and the second trenches T2 may be formed in positions corresponding to read bit lines 70.

According to an embodiment, an upper surface of the substrate 10 may be partially etched in a process of forming the first trenches T1 and the second trenches T2. For example, according to an embodiment, the semiconductor device 100c illustrated in FIG. 10 may be manufactured.

The semiconductor material layers 12 may be patterned by a process of forming the second sacrificial layers 11b, the first trenches T1, and the second trenches T2, and the semiconductor material layers 12 may be spaced apart from each other in the X-direction and the Y-direction. A portion of the semiconductor material layers 12 adjacent to the first trenches T1 may be referred to as first channel regions 13.

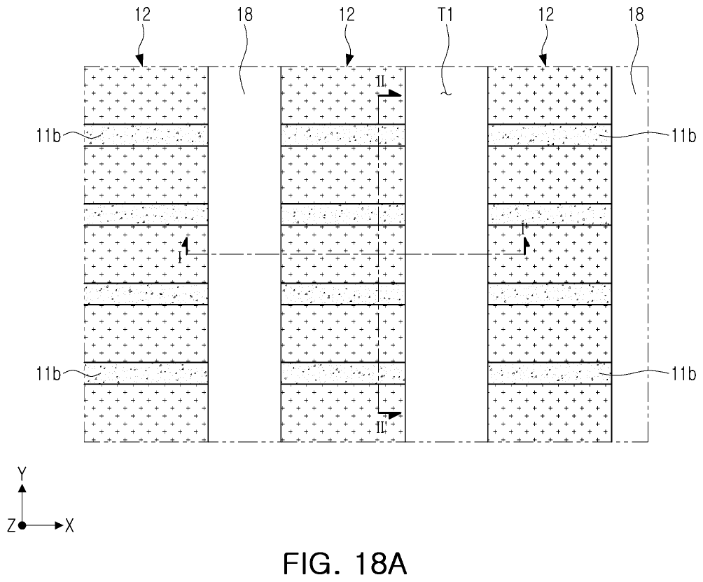

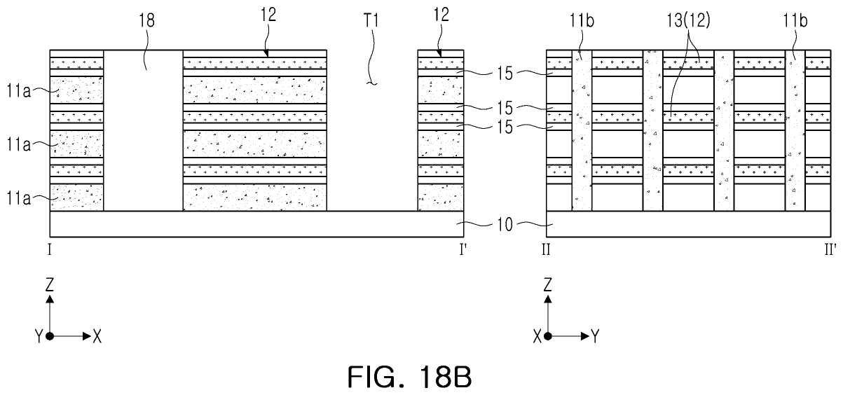

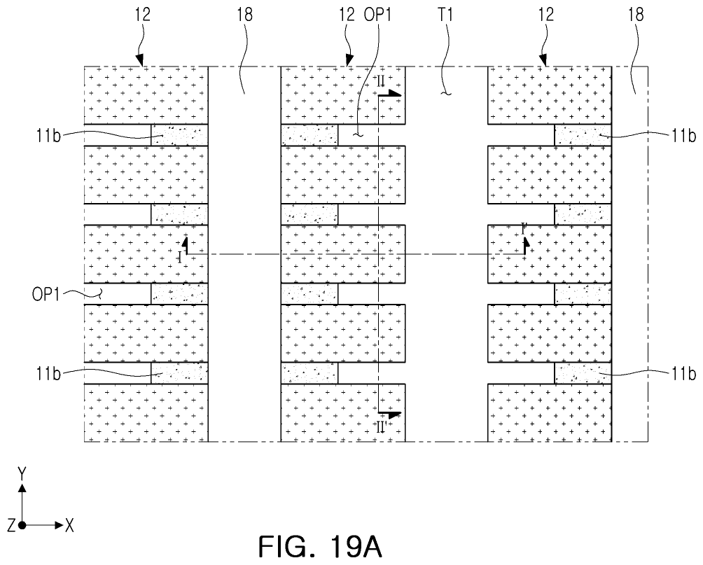

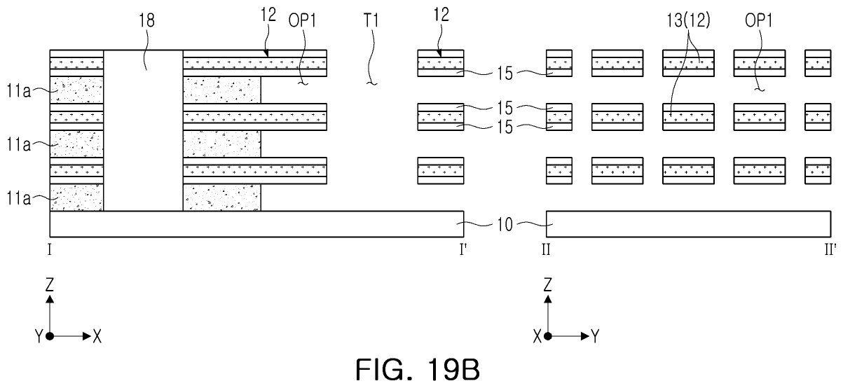

Referring to FIGS. 18A and 18B, first buried layers 18 filling the second trenches T2 may be formed. The first buried layers 18 may be formed only in the second trenches T2 by forming insulating material layers filling the first trenches T1 and the second trenches T2, and removing the insulating material layers filling the first trenches T1. The first buried layers 18 may include silicon oxide, silicon nitride, silicon oxynitride, silicon carbonitride, a low-κ dielectric, or a combination thereof. For example, the first buried layers 18 may include silicon oxide.

In an embodiment, an annealing process may be further performed after forming the first buried layers 18. The annealing process may supply oxygen atoms into the semiconductor material layers 12. For example, when the semiconductor material layers 12 include an oxide semiconductor material, the annealing process may reduce oxygen vacancies in the semiconductor material layers 12. The first channel regions 13 may be exposed by the first trenches T1, but charge storage regions 14 (FIG. 5) may not be exposed, such that a concentration of an oxygen vacancy in each of the first channel regions 13 may be lower than a concentration of an oxygen vacancy in each of the charge storage regions 14. Therefore, a carrier concentration and electrical conductivity of the charge storage regions 14 may be greater than those in the first channel regions 13. The term “exposed” (or “exposes,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

Referring to FIGS. 19A and 19B, the first sacrificial layers 11a and the second sacrificial layers 11b, exposed by the first trenches T1, may be partially etched. The first sacrificial layers 11a and the second sacrificial layers 11b may be etched to form first openings OP1. The first openings OP1 may extend in the horizontal direction from the first trenches T1, and may expose upper or lower surfaces of the dielectric layers 15 and side surfaces of the first sacrificial layers 11a. The dielectric layers 15 may include a material having etching selectivity with respect to the first sacrificial layers 11a and the second sacrificial layers 11b, and, thus, may not be etched in a process of forming the first openings OP1. The dielectric layers 15 may protect the semiconductor material layers 12 in the process of forming the first openings OP1.

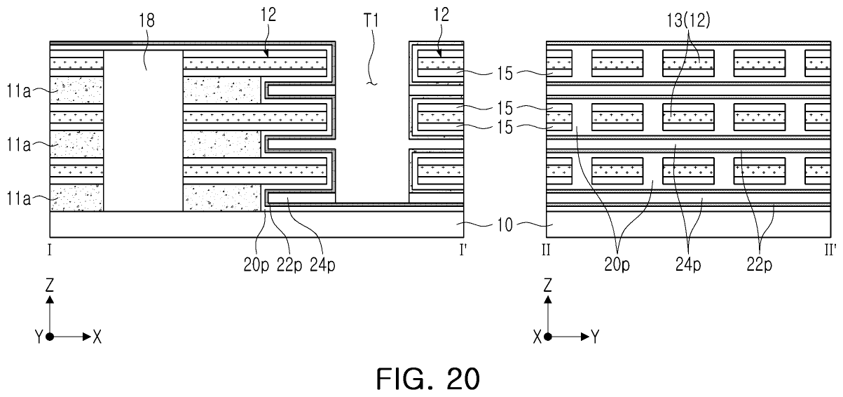

Referring to FIG. 20, a dielectric material layer 20p and a first insulating material layer 22p may be formed. The dielectric material layer 20p may be formed along the upper surface or the lower surface of the dielectric layers 15 exposed by the first trenches T1 and the first openings OP1 and the side surfaces of the first sacrificial layers 11a. The dielectric material layer 20p may also cover the upper surface of the substrate 10, an upper surface of an uppermost dielectric layer 15, and an upper surface of the first buried layer 18. In an embodiment, the dielectric material layer 20p may surround the first channel regions 13, and may extend in the Y-direction. For example, the dielectric material layer 20p may cover the upper surface or the lower surface of the dielectric layer 15, and may be in contact with side surfaces of the first channel regions 13. The first insulating material layer 22p may be conformally formed on the dielectric material layer 20p, and may extend in the Y-direction. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. A second insulating material layer 24p may be formed on the first insulating material layer 22p, and may be then etched, such that the first insulating material layer 22p may be exposed in the first trenches T1. The second insulating material layer 24p may fill the first openings OP1, and may extend in the Y-direction.

The first insulating material layer 22p and the second insulating material layer 24p may include silicon oxide, silicon nitride, silicon oxynitride, silicon carbonitride, a low-κ dielectric, or a combination thereof. The first insulating material layer 22p may include a material having etching selectivity with respect to the second insulating material layer 24p. For example, the first insulating material layer 22p may include silicon nitride, and the second insulating material layer 24p may include silicon oxide.

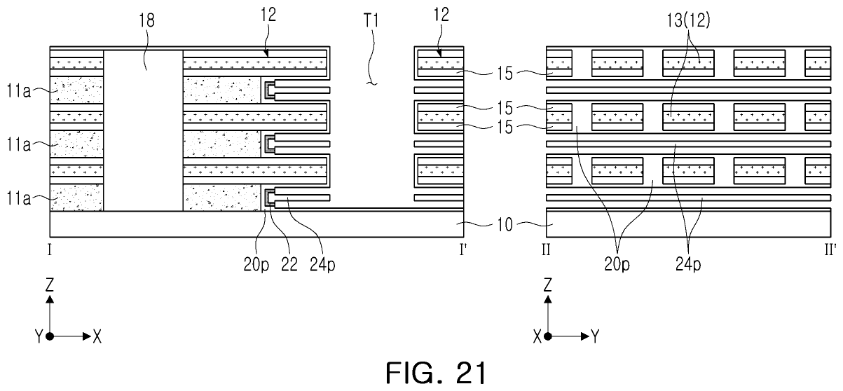

Referring to FIG. 21, the first insulating material layer 22p may be etched to form a insulating layer 22. The first insulating material layer 22p may include a material having etching selectivity with respect to the dielectric material layer 20p and the second insulating material layer 24p, and thus may be selectively etched. The first insulating layers 22 may be disposed between the semiconductor material layers 12, and may be spaced apart from each other in the vertical direction.

The dielectric material layer 20p and the second insulating material layer 24p, exposed by etching the first insulating material layer 22p, may be partially etched. For example, a thickness of a portion of the exposed dielectric material layer 20p and a thickness of a portion of the exposed second insulating material layer 24p may decrease in the vertical direction. Although the upper surface of the uppermost dielectric layer 15 and the upper surface of the first buried layer 18 are illustrated as being covered by the etched dielectric material layer 20p, this is not limited thereto. According to an embodiment, the upper surface of the uppermost dielectric layer 15 and the upper surface of the first buried layer 18 may be exposed.

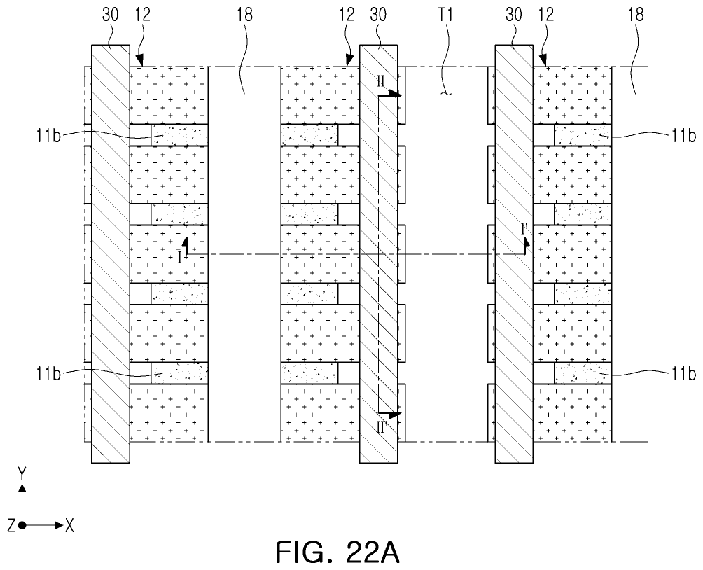

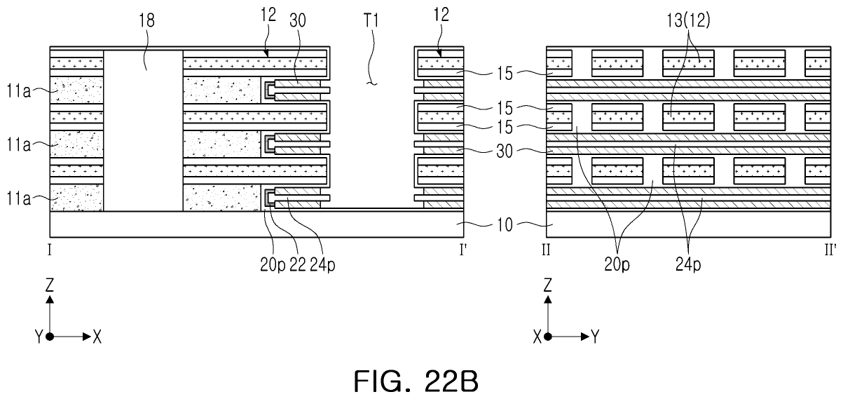

Referring to FIGS. 22A and 22B, write word lines 30 may be formed. The write word lines 30 may extend in the Y-direction, and may be spaced apart from each other in the X-direction. The write word lines 30 may be formed to overlap the first channel regions 13 of the semiconductor material layers 12 in the vertical direction. For example, two write word lines 30 may be formed between two adjacent semiconductor material layers 12 in the vertical direction, and the two write word lines 30 may be spaced apart from each other in the vertical direction, with the second insulating material layer 24p therebetween. A lowermost write word line 30 may be a dummy word line.

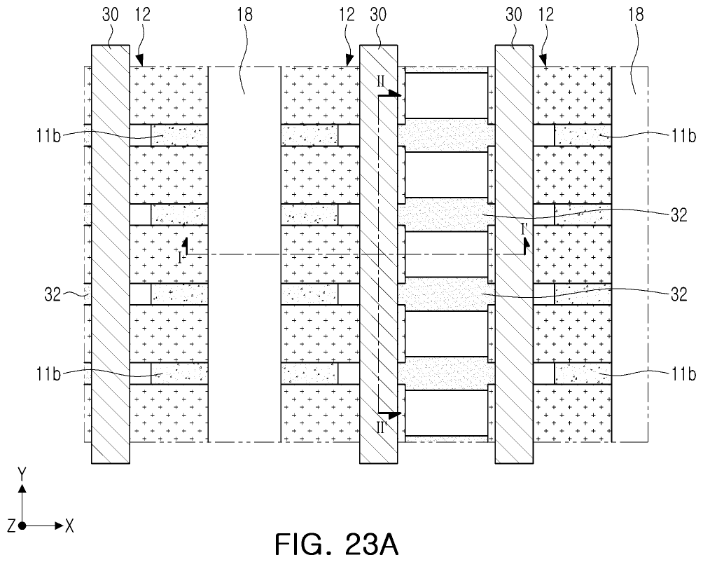

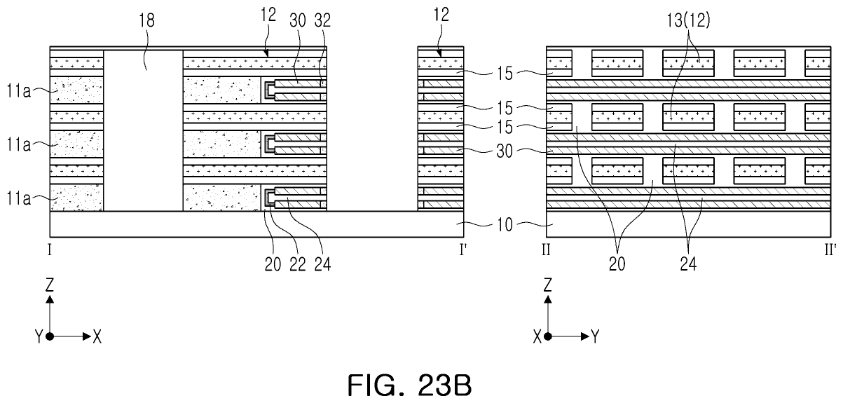

Referring to FIGS. 23A and 23B, capping layers 32 may be formed. The capping layers 32 may be prepared by forming a capping material layer contacting the write word lines 30 and filling the first trenches T1, and then anisotropically etching the capping material layer. The capping layers 32 may extend in the Y-direction, and may include openings in portions corresponding to write bit lines 40 to be described below. The capping layers 32 may include silicon oxide, silicon nitride, silicon oxynitride, silicon carbonitride, a low-κ dielectric, or a combination thereof.

In an embodiment, the semiconductor material layers 12, the dielectric layers 15, the dielectric material layer 20p, and the second insulating material layers 24p may be partially etched by the etching process. The dielectric material layer 20p and the second insulating material layers 24p may be etched to form a first gate dielectric pattern 20 and a second insulating layer 24.

Referring to FIGS. 24A to 24C, write bit lines 40 may be formed in the capping layers 32. Each of the write bit lines 40 may include a first conductive layer 42 and a first liner layer 44 surrounding the first conductive layer 42. The first liner layers 44 may extend in the horizontal direction to cover a side surface of the first conductive layer 42, and may extend in the vertical direction to contact a plurality of semiconductor material layers 12 spaced apart in the vertical direction. For example, the first liner layers 44 may be in contact with the first channel regions 13.

The first liner layers 44 may include a conductive material, and may include, for example, an oxide semiconductor material. Since both the first liner layers 44 and the semiconductor material layers 12 include an oxide semiconductor material, the first liner layers 44 may reduce electrical resistance between the semiconductor material layers 12 and the first conductive layer 42. In an embodiment, a concentration of an oxygen vacancy in each of the first liner layers 44 may be higher than a concentration of an oxygen vacancy in each of the first channel regions 13, and a carrier concentration and electrical conductivity of the first liner layers 44 may be higher than those of the first channel regions 13.

Referring to FIGS. 25A to 25C, the first buried layers 18 may be removed, and side surfaces of the semiconductor material layers 12 and side surfaces of the dielectric layers 15 may be exposed by second trenches T2. Portions of the semiconductor material layers 12 exposed by the second trenches T2 may be referred to as charge storage regions 14.

In an embodiment, a doping process may be further performed after the first buried layers 18 are removed. The doping process may provide impurities into the charge storage regions 14. For example, the impurities may include fluorine (F). Since the charge storage regions 14 include the impurities, a carrier concentration and electrical conductivity of the charge storage regions 14 may be higher than those of the first channel regions 13.

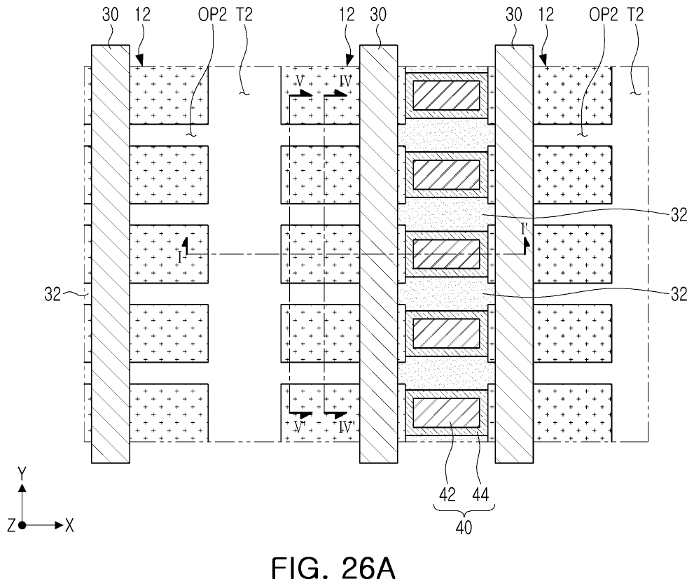

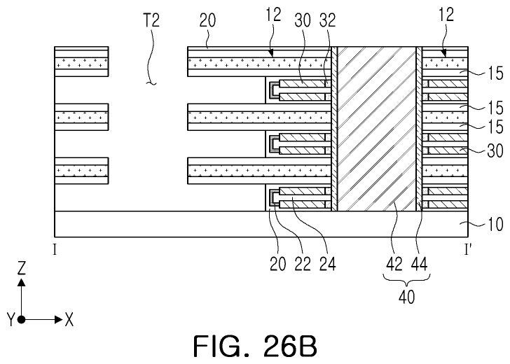

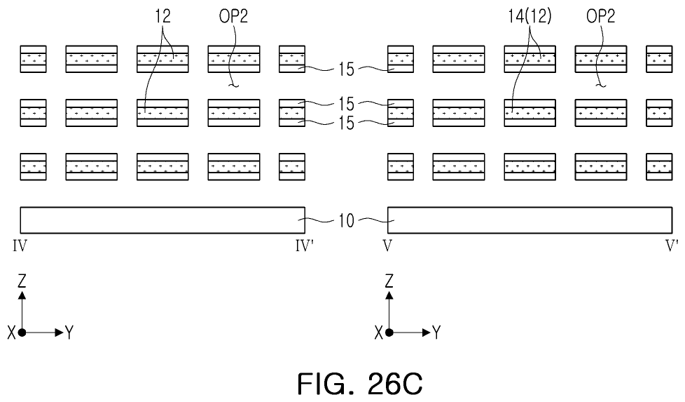

Referring to FIGS. 26A to 26C, the first sacrificial layers 11a and the second sacrificial layers 11b may be removed. The first sacrificial layers 11a and the second sacrificial layers 11b may be removed to form second openings OP2. The second openings OP2 may extend in the horizontal direction from the second trenches T2, and may expose the upper surface or the lower surface of the dielectric layers 15. The dielectric layers 15 may include a material having etching selectivity with respect to the first sacrificial layers 11a and the second sacrificial layers 11b, and, thus, may not be etched in a process of forming the second openings OP2. The dielectric layers 15 may protect the semiconductor material layers 12 in the process of forming the second openings OP2.

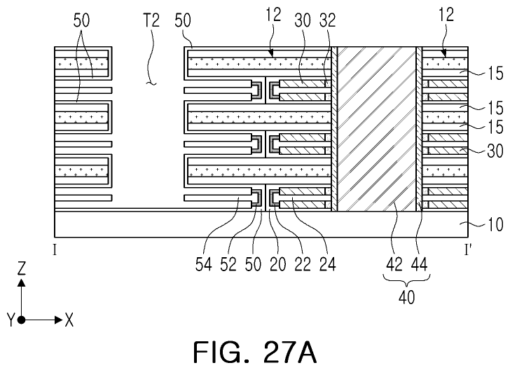

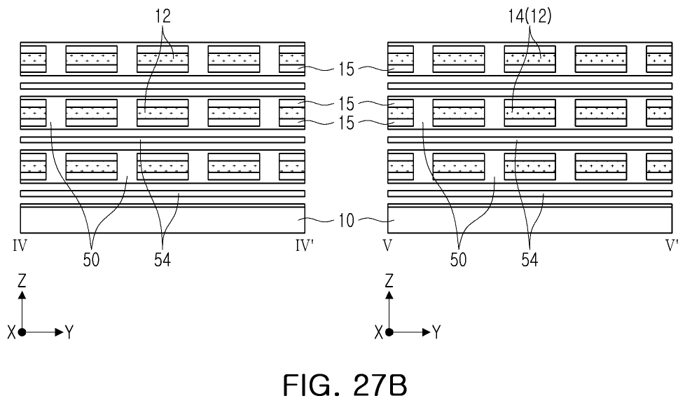

Referring to FIGS. 27A and 27B, a second gate dielectric pattern 50, a third insulating layer 52, and a fourth insulating layer 54 may be formed. The second gate dielectric pattern 50, the third insulating layer 52, and the fourth insulating layer 54 may be formed by the same or similar process as the dielectric material layer 20p, the first insulating layer 22, and the second insulating material layer 24p, described with reference to FIGS. 20 and 21. The second gate dielectric pattern 50, the third insulating layer 52, and the fourth insulating layer 54 may have the same or similar structure as the first gate dielectric pattern 20, the first insulating layer 22, and the second insulating layer 24, respectively.

The second gate dielectric pattern 50 may be formed along the upper surface or the lower surface of the dielectric layers 15. The second gate dielectric pattern 50 may also cover the upper surface of the substrate 10, the upper surface of the uppermost dielectric layer 15, and an upper surface of the write bit line 40. In an embodiment, the second gate dielectric pattern 50 may surround the charge storage regions 14, and may extend in the Y-direction. For example, the second gate dielectric pattern 50 may cover the upper surface or the lower surface of the dielectric layer 15, and may be in contact with side surfaces of the charge storage regions 14. The third insulating layer 52 may be formed by conformally depositing an insulating material layer on the second gate dielectric pattern 50 and then etching the insulating material layer. The third insulating layer 52 may extend in the Y-direction. The fourth insulating layer 54 may be formed on the third insulating layer 52, and may extend in the Y-direction.

The third insulating layer 52 and the fourth insulating layer 54 may include silicon oxide, silicon nitride, silicon oxynitride, silicon carbonitride, a low-κ dielectric, or a combination thereof. The third insulating layer 52 may include a material having etching selectivity with respect to the fourth insulating layer 54. For example, the third insulating layer 52 may include silicon nitride, and the fourth insulating layer 54 may include silicon oxide.

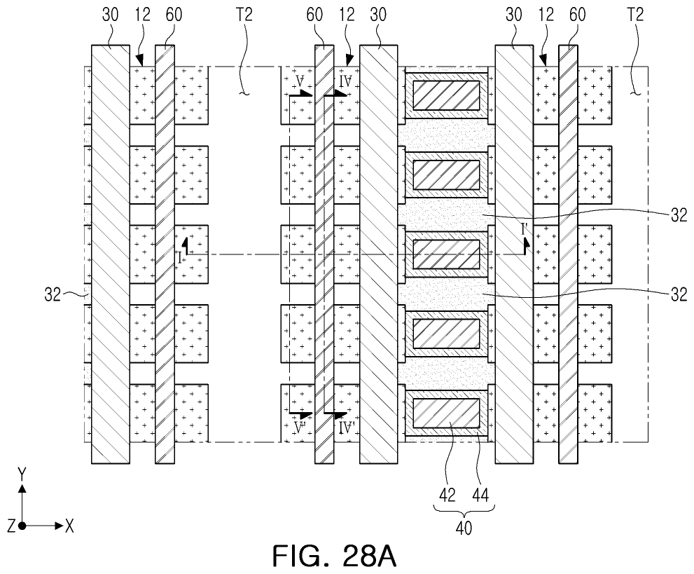

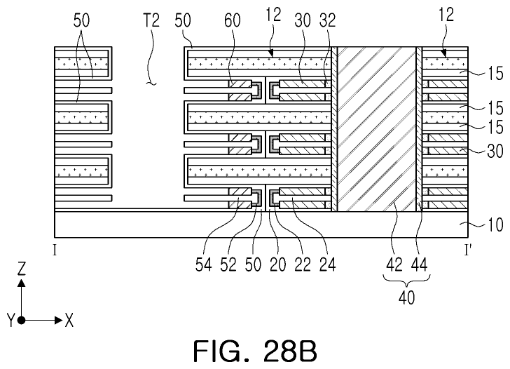

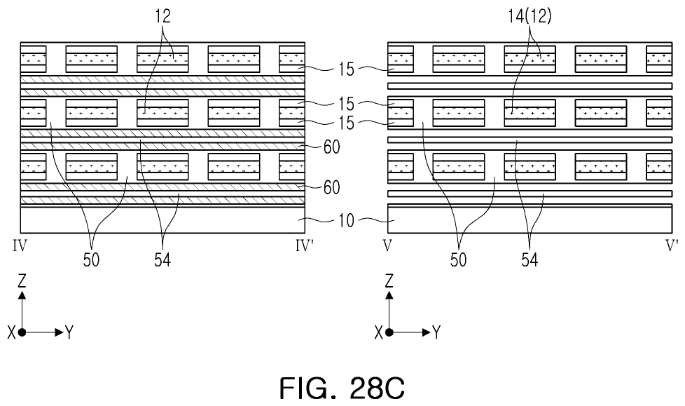

Referring to FIGS. 28A to 28C, read word lines 60 may be formed. The read word lines 60 may extend in the Y-direction, and may be spaced apart from each other in the X-direction. The read word lines 60 may overlap the charge storage regions 14 of the semiconductor material layers 12 in the vertical direction. For example, two read word lines 60 may be formed between two adjacent semiconductor material layers 12 in the vertical direction, and the two read word lines 60 may be spaced apart from each other in the vertical direction, with a fourth insulating layer 54 therebetween. A lowermost read word line 60 may be a dummy word line.

At least a portion of the read word line 60 may be disposed on the same level as the write word line 30 in the vertical direction. In an embodiment, upper and lower surfaces of the read word line 60 may be disposed on the same level as upper and lower surfaces of the write word line 30, respectively, in the vertical direction, but is not limited thereto. According to an embodiment, the upper and lower surfaces of the read word line 60 may not be disposed on the same level as the upper and lower surfaces of the write word line 30. As illustrated in FIGS. 8 and 9, according to an embodiment, a vertical thickness of the read word line 60 may be different from a vertical thickness of the write word line 30.

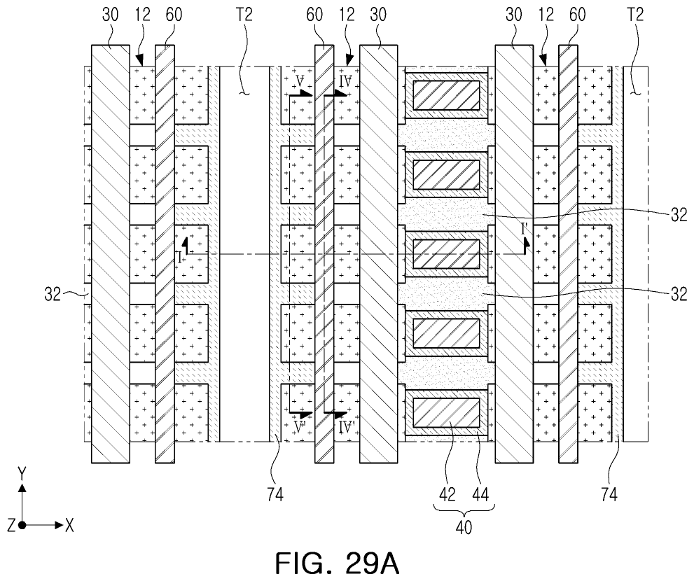

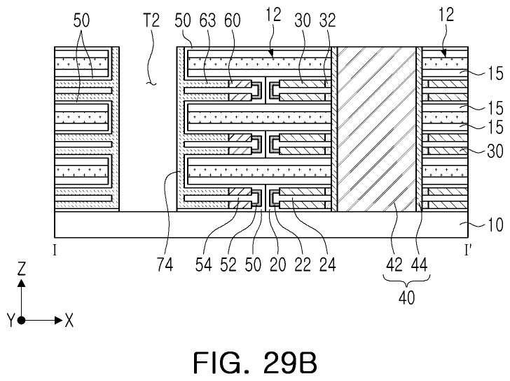

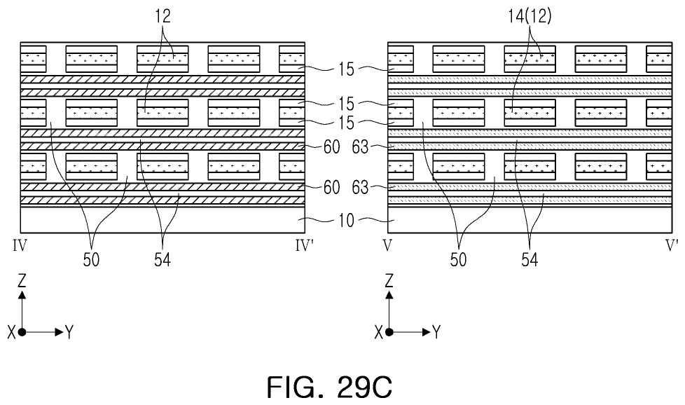

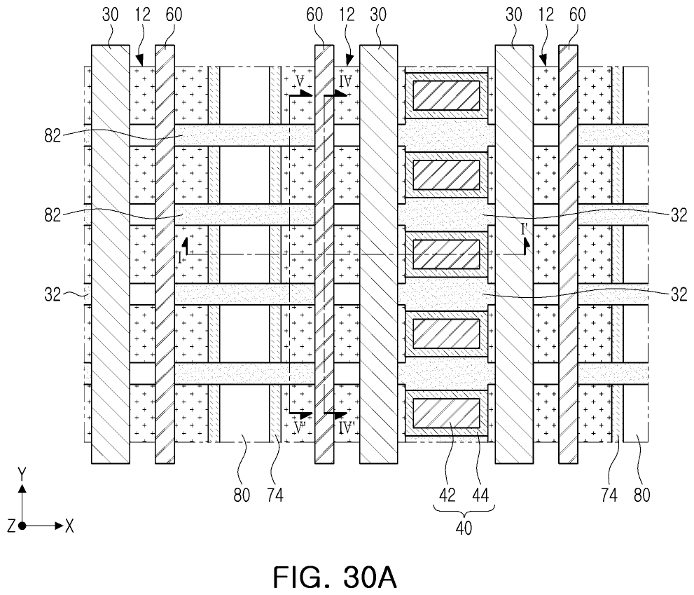

Referring to FIGS. 29A to 29C, second channel regions 63 and second liner layers 74 may be formed. The second channel regions 63 may be prepared by forming a semiconductor material layer to contact the read word lines 60, and then anisotropically etching the semiconductor material layer. The second liner layers 74 may be formed simultaneously with the second channel regions 63. For example, the second liner layers 74 may include the same material as the second channel regions 63, and may be formed integrally. The second channel regions 63 and the second liner layer 74 may include an oxide semiconductor material.

The second channel regions 63 may overlap the charge storage regions 14 in the vertical direction, and may extend in the horizontal direction. At least a portion of the second channel regions 63 may be disposed on the same level as the read word lines 60 and the write word lines 30 in the vertical direction. The second liner layers 74 may extend in the vertical direction, and may be in contact with the second channel regions 63.

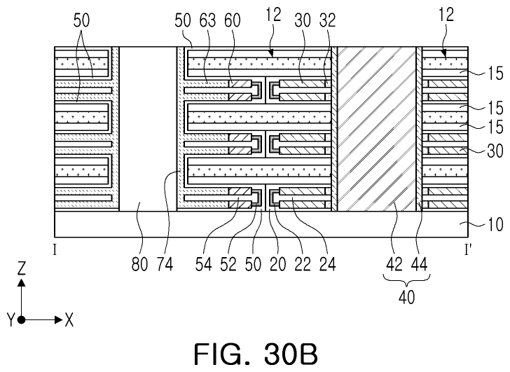

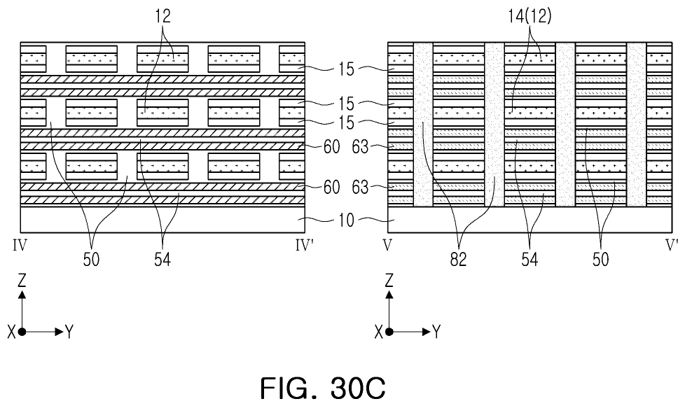

Referring to FIGS. 30A to 30C, second buried layers 80 may be formed on the second liner layers 74 to fill the second trenches T2. The second buried layers 80 may extend in the Y-direction in the second trenches T2. The second buried layers 80 may include silicon oxide, silicon nitride, silicon oxynitride, silicon carbonitride, a low-κ dielectric, or a combination thereof. For example, the second buried layers 80 may include silicon oxide.

After the second buried layers 80 are formed, the second buried layers 80 may be patterned by an anisotropic etching process. The etched second buried layers 80 may be spaced apart from each other in the Y-direction. The second channel regions 63 and the second liner layers 74 may be etched by the etching process. Spacer patterns 82 may be formed in a space from which a portion of the second buried layers 80 is removed. The spacer patterns 82 may extend in the X-direction and the vertical direction, and may be spaced apart from each other in the Y-direction. The spacer patterns 82 may be disposed between read word lines 60 adjacent to each other in the X-direction and between charge storage regions 14 adjacent to each other in the Y-direction. The spacer patterns 82 may include silicon oxide, silicon nitride, silicon oxynitride, silicon carbonitride, a low-κ dielectric, or a combination thereof. The spacer patterns 82 may include a material having etching selectivity with respect to the second buried layers 80.

Referring again to FIGS. 3 to 7, the second buried layers 80 may be removed, and the semiconductor device 100 may be manufactured by forming second conductive layers 72 in a space from which the second buried layers 80 are removed. The second conductive layers 72 and the second liner layers 74 may form read bit lines 70. The read bit lines 70 may extend in the vertical direction, and may be spaced apart from each other in the Y-direction. The read bit lines 70 may be electrically connected to the second channel regions 63.

According to embodiments of the technical idea of the present inventive concept, memory cells adjacent to each other in a horizontal direction may share a write bit line or a read bit line to reduce a size of a semiconductor device in the horizontal direction.

Various advantages and effects of the present inventive concept is not limited to the above-described contents, and will be more easily understood in the process of explaining specific embodiments.

While example embodiments have been shown and described above, it will be apparent to those skilled in the art that modifications and variations could be made without departing from the scope of the present inventive concept as defined by the appended claims.

What is claimed is:

1. A semiconductor device, comprising:
semiconductor material layers extending in a first horizontal direction and spaced apart from each other in the first horizontal direction, each of the semiconductor material layers including a first channel region and a charge storage region;
first word lines at least partially overlapping respective first channel regions of the semiconductor material layers in a vertical direction, and extending in a second horizontal direction, intersecting the first horizontal direction, the vertical direction perpendicular to the first and second horizontal directions;
first bit lines, each of the first bit lines being a first end of a respective one of the semiconductor material layers in the first horizontal direction, and extending in the vertical direction next to the first end adjacent to the first channel region;
second channel regions at least partially overlapping respective charge storage regions of the semiconductor material layers in the vertical direction; and
second bit lines, each of the second bit lines being a second end of a respective one of the semiconductor material layers in the first horizontal direction, and extending in the vertical direction next to the second end adjacent to the charge storage region,
wherein each of the first bit lines includes a first conductive layer and a first liner layer extending around a side surface of the first conductive layer, and
respective first liner layers of the first bit lines are in contact with the first channel regions, extend in the vertical direction, and include an oxide semiconductor material.

2. The semiconductor device of claim 1, wherein each of the semiconductor material layers comprises a unitary member including the charge storage region and the first channel region of a same material.

3. The semiconductor device of claim 1, wherein the first word lines are disposed symmetrically with respect to the first bit lines.

4. The semiconductor device of claim 1, wherein the second channel regions are disposed symmetrically with respect to the second bit lines.

5. The semiconductor device of claim 1, wherein each of the charge storage regions and the first channel regions includes an oxide semiconductor material.

6. The semiconductor device of claim 5, wherein a concentration of an oxygen vacancy in each of the charge storage regions is greater than a concentration of an oxygen vacancy in each of the first channel regions.

7. The semiconductor device of claim 5, wherein a concentration of an oxygen vacancy in each of the first liner layers is greater than a concentration of an oxygen vacancy in each of the first channel regions.

8. The semiconductor device of claim 5, wherein each of the charge storage regions includes fluorine (F).

9. The semiconductor device of claim 1, wherein at least a portion of the second channel regions is coplanar with the first word lines.

10. The semiconductor device of claim 1, wherein a thickness of each of the second channel regions in the vertical direction is different from a thickness of each of the first word lines in the vertical direction.

11. The semiconductor device of claim 1, further comprising second word lines contacting the second channel regions and disposed between the second channel regions and the first word lines.

12. The semiconductor device of claim 1, wherein each of the second bit lines includes a second conductive layer and a second liner layer extending around side surfaces of the second conductive layer, and
respective second liner layers of the second bit lines are in contact with the second channel regions, extend in the vertical direction, and include an oxide semiconductor material.

13. The semiconductor device of claim 12, wherein each of the second liner layers includes a unitary member including the second liner layer and the second channel region of a same material.

14. The semiconductor device of claim 1, further comprising dielectric layers extending in a horizontal direction between the first word lines and the semiconductor material layers and between the second channel regions and the semiconductor material layers.

15. The semiconductor device of claim 14, wherein the dielectric layers are in contact with at least one of upper or lower surfaces of the semiconductor material layers.

16. A semiconductor device, comprising:
memory cells, each of the memory cells including a first transistor including a first channel region, a second transistor including a second channel region, and a charge storage region coplanar with the first channel region, at least partially overlapping the second channel region in a vertical direction, and disposed in a first horizontal direction perpendicular to the vertical direction;
a first bit line extending in the vertical direction between the memory cells and electrically connected to respective first transistors in the memory cells; and
a second bit line extending in the vertical direction between the memory cells and electrically connected to respective second transistors in the memory cells,
wherein the memory cells include a first memory cell and a second memory cell, adjacent to each other in the first horizontal direction,
the first memory cell and the second memory cell share the first bit line,
the first bit line includes a first conductive layer and a first liner layer extending around a side surface of the first conductive layer, and
the first liner layer extends in the vertical direction and is in contact with respective first channel regions in the first transistors.

17. The semiconductor device of claim 16, wherein the first bit line is in contact with the first channel regions of the first transistors of the first memory cell and the second memory cell.

18. The semiconductor device of claim 16, wherein the memory cells include a third memory cell adjacent to the first memory cell in the first horizontal direction,
the first memory cell is between the second memory cell and the third memory cell, and
the first memory cell and the third memory cell share the second bit line.

19. The semiconductor device of claim 16, wherein respective first transistors in the memory cells include first word lines at least partially overlapping the first channel regions in the vertical direction, and
at least a portion of the first word lines are coplanar with the second channel regions.

20. A semiconductor device, comprising:
a semiconductor material layer extending in a first horizontal direction and including a first channel region and a charge storage region;
a first word line at least partially overlapping the first channel region of the semiconductor material layer in a vertical direction and extending in a second horizontal direction, intersecting the first horizontal direction, the vertical direction being perpendicular to the first and second horizontal directions;
a second channel region at least partially overlapping the charge storage region of the semiconductor material layer in the vertical direction;
a second word line contacting the second channel region and extending in the second horizontal direction between the second channel region and the first word line;
a first bit line extending in the vertical direction from one side of the first channel region of the semiconductor material layer; and
a second bit line extending in the vertical direction from one side of the second channel region.
